(19) United States
(12) Patent Application Publication
(10) Pub. No.: US 2024/0047377 A1
(43) Pub. Date: Feb. 8, 2024

(54) HIGH-FREQUENCY MODULE AND COMMUNICATION DEVICE

(71) Applicant: Murata Manufacturing Co., Ltd., Kyoto (JP)

(72) Inventors: Takanori UEJIMA, Kyoto (JP); Hiromichi KITAJIMA, Kyoto (JP); Dai NAKAGAWA, Kyoto (JP)

(21) Appl. No.: 18/492,051

(22) Filed: Oct. 23, 2023

Related U.S. Application Data
(63) Continuation of application No. PCT/JP2022/017827, filed on Apr. 14, 2022.

(30) Foreign Application Priority Data
Apr. 26, 2021 (JP) 2021-074437

(51) Int. Cl. H01L 23/552; H01L 25/16

(52) U.S. Cl. CPC H01L 23/552; H01L 25/16

(57) ABSTRACT

A high-frequency module includes a mounting substrate, a first electronic component, a second electronic component, a resin layer, and a metal electrode layer. The first electronic component and the second electronic component are disposed on a first main surface of the mounting substrate. The metal electrode layer covers at least a part of the resin layer, and overlaps with at least a part of the first electronic component and at least a part of the second electronic component in a plan view. At least a part of a main surface of the first electronic component opposite to the mounting substrate side is in contact with the metal electrode layer. The metal electrode layer has a through-portion between a first signal terminal of the first electronic component and a second signal terminal of the second electronic component in the plan view.

### CROSS REFERENCE TO RELATED APPLICATION

This is a continuation of International Application No. PCT/JP2022/017827 filed on Apr. 14, 2022 which claims priority from Japanese Patent Application No. 2021-074437 filed on Apr. 26, 2021. The contents of these applications are incorporated herein by reference in their entireties.

### BACKGROUND ART

### Technical Field

The present disclosure generally relates to a high-frequency module and a communication device, and more specifically, to a high-frequency module including a mounting substrate and a communication device including the high-frequency module.

Patent Document 1 discloses a module (high-frequency module) including a module substrate (mounting substrate), an electronic component mounted on the mounting surface of the module substrate, and a resin layer provided on the mounting surface of the module substrate to coat a side surface (outer peripheral surface) of the electronic component. In the module described in Patent Document 1, a metal film (metal electrode layer) is formed on at least a part of an upper surface of each of the electronic component and the resin layer.
Patent Document 1: International Publication No. WO 2014/013831

### BRIEF SUMMARY

In the module described in Patent Document 1, isolation between terminals is decreased, in some cases.

The present disclosure provides a high-frequency module and a communication device capable of reducing a decrease in isolation between terminals.

According to an aspect of the present disclosure, there is provided a high-frequency module including a mounting substrate, a first electronic component, a second electronic component, a resin layer, and a metal electrode layer. The mounting substrate has a first main surface and a second main surface facing each other. The first electronic component and the second electronic component are disposed on the first main surface of the mounting substrate. The resin layer is disposed on the first main surface of the mounting substrate, and covers at least a part of an outer peripheral surface of the first electronic component and at least a part of an outer peripheral surface of the second electronic component. The metal electrode layer covers at least a part of the resin layer, and overlaps with at least a part of the first electronic component and at least a part of the second electronic component in a plan view in a thickness direction of the mounting substrate. At least a part of a main surface of the first electronic component opposite to a mounting substrate side is in contact with the metal electrode layer. The first electronic component has a first signal terminal. The second electronic component has a second signal terminal. The metal electrode layer has a through-portion between the first signal terminal and the second signal terminal in the plan view in the thickness direction of the mounting substrate.

According to another aspect of the present disclosure, there is provided a high-frequency module including a mounting substrate, a first electronic component, a second electronic component, a first metal member, a second metal member, a resin layer, and a metal electrode layer. The mounting substrate has a first main surface and a second main surface facing each other. The first electronic component and the second electronic component are disposed on the first main surface of the mounting substrate. The first metal member is disposed on a main surface of the first electronic component opposite to a mounting substrate side. The second metal member is disposed on a main surface of the second electronic component opposite to the mounting substrate side. The resin layer is disposed on the first main surface of the mounting substrate, and covers at least a part of an outer peripheral surface of the first electronic component, at least a part of an outer peripheral surface of the second electronic component, at least a part of an outer peripheral surface of the first metal member, and at least a part of an outer peripheral surface of the second metal member. The metal electrode layer covers at least a part of the resin layer, and overlaps with at least a part of the first metal member and at least a part of the second metal member in a plan view in a thickness direction of the mounting substrate. At least a part of a main surface of the first metal member opposite to the mounting substrate side is in contact with the metal electrode layer. At least a part of a main surface of the second metal member opposite to the mounting substrate side is in contact with the metal electrode layer. The first electronic component has a first signal terminal. The second electronic component has a second signal terminal. The metal electrode layer has a through-portion between the first signal terminal and the second signal terminal in the plan view in the thickness direction of the mounting substrate.

According to still another aspect of the present disclosure, there is provided a high-frequency module including a mounting substrate, an electronic component, a resin layer, and a metal electrode layer. The mounting substrate has a first main surface and a second main surface facing each other. The electronic component is disposed on the first main surface of the mounting substrate. The resin layer is disposed on the first main surface of the mounting substrate, and covers at least a part of an outer peripheral surface of the electronic component. The metal electrode layer covers at least a part of the resin layer, and overlaps at least a part of the electronic component in a plan view in a thickness direction of the mounting substrate. At least a part of a main surface of the electronic component opposite to a mounting substrate side is in contact with the metal electrode layer. The electronic component has a first signal terminal and a second signal terminal. The metal electrode layer has a through-portion between the first signal terminal and the second signal terminal in the plan view in the thickness direction of the mounting substrate.

According to an aspect of the present disclosure, there is provided a communication device including the high-frequency module and a signal processing circuit. The signal processing circuit is connected to the high-frequency module.

According to an aspect of the present disclosure, a high-frequency module and a communication device can reduce a decrease in isolation between terminals.

### BRIEF DESCRIPTION OF THE DRAWINGS

FIG. 1 is a schematic diagram of a communication device according to Embodiment 1.

FIG. 2 is a plan view of a high-frequency module according to Embodiment 1.

FIG. 3 is a cross-sectional diagram of the high-frequency module according to Embodiment 1.

FIG. 4 is a cross-sectional diagram of a high-frequency module according to Embodiment 2.

FIG. 5 is a cross-sectional diagram of a high-frequency module according to Embodiment 3.

FIG. 6 is a cross-sectional diagram of a high-frequency module according to Embodiment 4.

FIG. 7 is a cross-sectional diagram of a high-frequency module according to Embodiment 5.

FIG. 8 is a plan view of a high-frequency module according to Embodiment 6.

FIG. 9 is a plan view of a high-frequency module according to Embodiment 7.

FIG. 10 is a cross-sectional diagram of a high-frequency module according to Embodiment 8.

FIG. 11 is a cross-sectional diagram of a high-frequency module according to Embodiment 9.

FIG. 12 is a cross-sectional diagram of a high-frequency module according to Embodiment 10.

FIG. 13 is a cross-sectional diagram of a high-frequency module according to Embodiment 11.

FIG. 14 is a cross-sectional diagram of a high-frequency module according to Embodiment 12.

### DETAILED DESCRIPTION

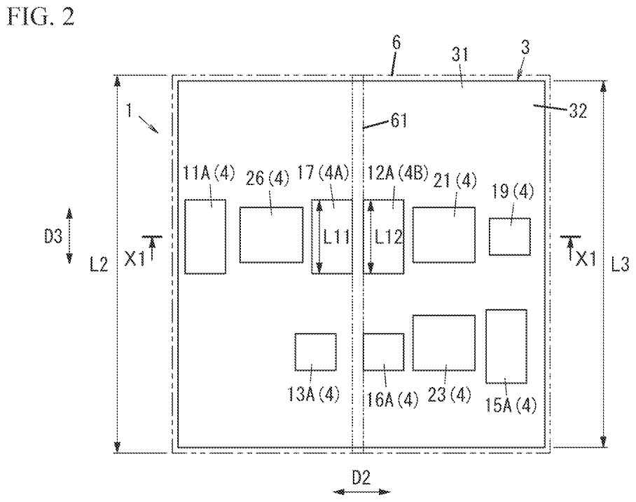

Hereinafter, high-frequency modules and communication devices according to Embodiments 1 to 12 will be described with reference to the accompanying drawings. All of FIGS. 2 to 14 referred to in the following embodiments and the like are schematic diagrams, and each ratio of a size or a thickness of each component in FIGS. 2 to 14 does not necessarily reflect an actual dimensional ratio.

### Embodiment 1

### (1) High-Frequency Module

A configuration of a high-frequency module 1 according to Embodiment 1 will be described with reference to the drawings.

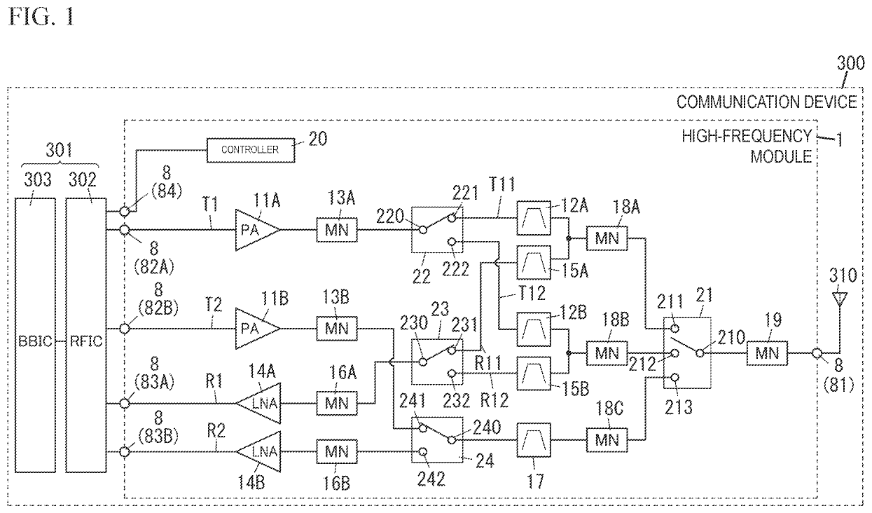

The high-frequency module 1 is used, for example, in a communication device 300 as illustrated in FIG. 1. The communication device 300 is, for example, a mobile phone such as a smartphone. The communication device 300 is not limited to the mobile phone, and may be, for example, a wearable terminal or the like such as a smart watch. The high-frequency module 1 is, for example, a module capable of supporting a fourth generation mobile communication (4G) standard, a fifth generation mobile communication (5G) standard, and the like. The 4G standard is, for example, a third generation partnership project (3GPP) long term evolution (LTE) standard. The 5G standard is, for example, a 5G new radio (NR). The high-frequency module 1 is, for example, a module capable of supporting carrier aggregation and dual connectivity.

The communication device 300 performs communication in a plurality of communication bands. More specifically, the communication device 300 performs transmission of transmission signals in the plurality of communication bands and reception of reception signals in the plurality of communication bands.

Some of the transmission signals and the reception signals of the plurality of communication bands are signals of a frequency division duplex (FDD). The transmission signal and the reception signal of the plurality of communication bands are not limited to the FDD signals, and may be signals of time division duplex (TDD). The FDD is a wireless communication technology in which different frequency bandwidths are assigned to transmission and reception in wireless communication, and transmission and reception are performed. The TDD is a wireless communication technology in which the same frequency bandwidth is assigned to transmission and reception in wireless communication, and transmission and reception are switched by the hour.

### (2) Circuit Configuration of High-Frequency Module

Hereinafter, a circuit configuration of the high-frequency module 1 according to Embodiment 1 will be described with reference to FIG. 1.

As illustrated in FIG. 1, the high-frequency module 1 according to Embodiment 1 includes a plurality of (two in the illustrated example) power amplifiers 11A and 11B, a plurality of (two in the illustrated example) transmission filters 12A and 12B, and a plurality of (two in the illustrated example) reception filters 15A and 15B, a plurality of (two in the illustrated example) low-noise amplifiers 14A and 14B, and a transmission and reception filter 17. In addition, the high-frequency module 1 includes a plurality of (two in the illustrated example) output matching circuits 13A and 13B, a plurality of (two in the illustrated example) input matching circuits 16A and 16B, and a plurality of (four in the illustrated example) matching circuits 18A to 18C and 19. The high-frequency module 1 further includes a first switch 21, a second switch 22, a third switch 23, a fourth switch 24, and a controller 20. The high-frequency module 1 further includes a plurality of (four in the illustrated example) external connection electrodes 8.

(2.1) Power Amplifier

Each of the plurality of power amplifiers 11A and 11B illustrated in FIG. 1 is an amplifier that amplifies a transmission signal. The power amplifier 11A is provided between a signal input terminal 82A and the plurality of transmission filters 12A and 12B in a transmission path T1 connecting an antenna terminal 81 and the signal input terminal 82A, which will be described below. The power amplifier 11B is provided between a signal input terminal 82B and the transmission and reception filter 17 in a transmission path T2 connecting the antenna terminal 81 and the signal input terminal 82B, which will be described below. Each of the plurality of power amplifiers 11A and 11B has an input terminal (not illustrated) and an output terminal (not illustrated). The input terminal of the power amplifier 11A is connected to an external circuit (for example, a signal processing circuit 301) with the signal input terminal 82A interposed therebetween. The output terminal of the power amplifier 11A is connected to the plurality of transmission filters 12A and 12B. The input terminal of the power amplifier 11B is connected to an external circuit (for example, the signal processing circuit 301) with the signal input terminal 82B interposed therebetween. The output terminal of the power amplifier 11B is connected to the transmission and reception filter 17. The plurality of power amplifiers 11A and 11B are controlled by, for example, the controller 20. The power amplifier 11A may be directly or indirectly connected to the plurality of transmission filters 12A and 12B. In the example in FIG. 1, the power amplifier 11A is connected to the plurality of transmission filters 12A and 12B with the output matching circuit 13A interposed therebetween. The power amplifier 11B may be directly or indirectly connected to the transmission and reception filter 17. In the example in FIG. 1, the power amplifier 11B is connected to the transmission and reception filter 17 with the output matching circuit 13B interposed therebetween.

The transmission path T1 includes a first transmission path T11 and a second transmission path T12. As illustrated in FIG. 1, the first transmission path T11 is a path passing through the signal input terminal 82A, the power amplifier 11A, the output matching circuit 13A, the second switch 22, the transmission filter 12A, the matching circuit 18A, the first switch 21, the matching circuit 19, and the antenna terminal 81. As illustrated in FIG. 1, the second transmission path T12 is a path passing through the signal input terminal 82A, the power amplifier 11A, the output matching circuit 13A, the second switch 22, the transmission filter 12B, the matching circuit 18B, the first switch 21, the matching circuit 19, and the antenna terminal 81.

(2.2) Transmission Filter

The plurality of transmission filters 12A and 12B illustrated in FIG. 1 are filters that pass transmission signals in communication bands different from each other. The plurality of transmission filters 12A and 12B are provided between the power amplifier 11A and the first switch 21 in the transmission path T1. Each of the plurality of transmission filters 12A and 12B passes a transmission signal in a transmission bandwidth of the corresponding communication band, among high-frequency signals amplified by the power amplifier 11A.

(2.3) Reception Filter

The plurality of reception filters 15A and 15B illustrated in FIG. 1 are filters that pass reception signals in communication bands different from each other. The plurality of reception filters 15A and 15B are provided between the first switch 21 and the low-noise amplifier 14A in a reception path R1 connecting an antenna terminal 81 and a signal output terminal 83A, which will be described below. Each of the plurality of reception filters 15A and 15B passes a reception signal in a reception bandwidth of the corresponding communication band, among high-frequency signals input from the antenna terminal 81.

(2.4) Transmission and Reception Filter

The transmission and reception filter 17 illustrated in FIG. 1 is a filter that passes a transmission signal of one communication band and a reception signal of one communication band. The transmission and reception filter 17 is provided between the first switch 21 and the power amplifier 11B in the transmission path T2. In addition, the transmission and reception filter 17 is provided between the first switch 21 and the low-noise amplifier 14B in a reception path R2 connecting the antenna terminal 81 and the signal output terminal 83B, which will be described below. The transmission and reception filter 17 passes a transmission signal in a transmission bandwidth of the corresponding communication band, among high-frequency signals amplified by the power amplifier 11B. The transmission and reception filter 17 passes a reception signal in a reception bandwidth of the corresponding communication band, among high-frequency signals input from the antenna terminal 81.

The reception path R1 includes a first reception path R11 and a second reception path R12. As illustrated in FIG. 1, the first reception path R11 is a path passing through the signal output terminal 83A, the low-noise amplifier 14A, the input matching circuit 16A, the third switch 23, the reception filter 15A, the matching circuit 18A, the first switch 21, the matching circuit 19, and the antenna terminal 81. As illustrated in FIG. 1, the second reception path R12 is a path passing through the signal output terminal 83A, the low-noise amplifier 14A, the input matching circuit 16A, the third switch 23, the reception filter 15B, the matching circuit 18B, the first switch 21, the matching circuit 19, and the antenna terminal 81.

(2.5) Low-Noise Amplifier

Each of the plurality of low-noise amplifiers 14A and 14B illustrated in FIG. 1 is an amplifier that amplifies a reception signal with a low noise. The low-noise amplifier 14A is provided between the plurality of reception filters 15A and 15B and the signal output terminal 83A in the reception path R1. The low-noise amplifier 14B is provided between the transmission and reception filter 17 and the signal output terminal 83B in the reception path R2. Each of the plurality of low-noise amplifiers 14A and 14B has an input terminal (not illustrated) and an output terminal (not illustrated). The input terminal of the low-noise amplifier 14A is connected to the input matching circuit 16A. The output terminal of the low-noise amplifier 14A is connected to an external circuit (for example, the signal processing circuit 301) with the signal output terminal 83A interposed therebetween. The input terminal of the low-noise amplifier 14B is connected to the input matching circuit 16B. The output terminal of the low-noise amplifier 14B is connected to an external circuit (for example, the signal processing circuit 301) with the signal output terminal 83B interposed therebetween.

(2.6) Output Matching Circuit

As illustrated in FIG. 1, the output matching circuit 13A is provided between the power amplifier 11A and the plurality of transmission filters 12A and 12B in the transmission path T1. The output matching circuit 13A is a circuit for performing impedance matching between the power amplifier 11A and the plurality of transmission filters 12A and 12B. As illustrated in FIG. 1, the output matching circuit 13B is provided between the power amplifier 11B and the transmission and reception filter 17 in the transmission path T2. The output matching circuit 13B is a circuit for performing impedance matching between the power amplifier 11B and the transmission and reception filter 17.

The output matching circuit 13A has a configuration including an inductor. The inductor of the output matching circuit 13A is provided on an output side of the power amplifier 11A in the transmission path T1. The output matching circuit 13B has a configuration including an inductor. The inductor of the output matching circuit 13B is provided on an output side of the power amplifier 11B in the transmission path T2. Each of the output matching circuits 13A and 13B is not limited to having the configuration including one inductor, and may have, for example, a configuration including a plurality of inductors, or a configuration including a plurality of inductors and a plurality of capacitors. In short, each of the output matching circuits 13A and 13B includes at least one inductor.

(2.7) Input Matching Circuit

As illustrated in FIG. 1, the input matching circuit 16A is provided between the plurality of reception filters 15A and 15B and the low-noise amplifier 14A in the reception path R1. The input matching circuit 16A is a circuit for performing impedance matching between the plurality of reception filters 15A and 15B and the low-noise amplifier 14A. As illustrated in FIG. 1, the input matching circuit 16B is provided between the transmission and reception filter 17 and the low-noise amplifier 14B in the reception path R2. The input matching circuit 16B is a circuit for performing impedance matching between the transmission and reception filter 17 and the low-noise amplifier 14B.

The input matching circuit 16A has a configuration including an inductor. The inductor of the input matching circuit 16A is provided on an input side of the low-noise amplifier 14A in the reception path R1. The input matching circuit 16B has a configuration including an inductor. The inductor of the input matching circuit 16B is provided on an input side of the low-noise amplifier 14B in the reception path R2. Each of the input matching circuits 16A and 16B is not limited to having the configuration including one inductor, and may have, for example, a configuration including a plurality of inductors, or a configuration including a plurality of inductors and a plurality of capacitors. In short, each of the input matching circuits 16A and 16B includes at least one inductor.

(2.8) Matching Circuit

As illustrated in FIG. 1, the matching circuit 18A is provided between the transmission filter 12A and the reception filter 15A, and the first switch 21. The matching circuit 18A is a circuit for performing impedance matching between the first switch 21, and the transmission filter 12A and the reception filter 15A. As illustrated in FIG. 1, the matching circuit 18B is provided between the transmission filter 12B and the reception filter 15B, and the first switch 21. The matching circuit 18B is a circuit for performing impedance matching between the first switch 21, and the transmission filter 12B and the reception filter 15B. As illustrated in FIG. 1, the matching circuit 18C is provided between the transmission and reception filter 17 and the first switch 21. The matching circuit 18C is a circuit for impedance matching between the first switch 21 and the transmission and reception filter 17.

As illustrated in FIG. 1, the matching circuit 19 is provided between the first switch 21 and the antenna terminal 81. The matching circuit 19 is a circuit for performing impedance matching between an antenna 310 connected to the antenna terminal 81 and the first switch 21.

(2.9) First Switch

The first switch 21 illustrated in FIG. 1 switches filters to be connected to the antenna terminal 81 among the plurality of transmission filters 12A and 12B, the plurality of reception filters 15A and 15B, and the transmission and reception filter 17. In other words, the first switch 21 is a switch for switching a path to be connected to the antenna 310. The first switch 21 has a common terminal 210 and a plurality of (three in the illustrated example) selection terminals 211 to 213. The common terminal 210 is connected to the antenna terminal 81. The selection terminal 211 among the plurality of selection terminals 211 to 213 is connected to the transmission filter 12A and the reception filter 15A. In addition, the selection terminal 212 among the plurality of selection terminals 211 to 213 is connected to the transmission filter 12B and the reception filter 15B. The selection terminal 213 among the plurality of selection terminals 211 to 213 is connected to the transmission and reception filter 17.

The first switch 21 switches connection states between the common terminal 210 and the plurality of selection terminals 211 to 213. The first switch 21 is controlled by, for example, the signal processing circuit 301. The first switch 21 electrically connects the common terminal 210 to at least one of the plurality of selection terminals 211 to 213, according to a control signal from an RF signal processing circuit 302 of the signal processing circuit 301.

(2.10) Second Switch

The second switch 22 illustrated in FIG. 1 switches transmission filters to be connected to the power amplifier 11A among the plurality of transmission filters 12A and 12B. The second switch 22 is a switch for switching a path to be connected to the power amplifier 11A. The second switch 22 has a common terminal 220 and a plurality of (two in the illustrated example) selection terminals 221 and 222. The common terminal 220 is connected to the power amplifier 11A. The selection terminal 221 among the plurality of selection terminals 221 and 222 is connected to the transmission filter 12A. In addition, the selection terminal 222 among the plurality of selection terminals 221 and 222 is connected to the transmission filter 12B.

The second switch 22 switches connection states between the common terminal 220 and the plurality of selection terminals 221 and 222. The second switch 22 is controlled by, for example, the signal processing circuit 301. The second switch 22 electrically connects the common terminal 220 to at least one of the plurality of selection terminals 221 and 222, according to a control signal from the RF signal processing circuit 302 of the signal processing circuit 301.

(2.11) Third Switch

The third switch 23 illustrated in FIG. 1 switches reception filters to be connected to the low-noise amplifier 14A among the plurality of reception filters 15A and 15B. The third switch 23 is a switch for switching a path to be connected to the low-noise amplifier 14A. The third switch 23 has a common terminal 230 and a plurality of (two in the illustrated example) selection terminals 231 and 232. The common terminal 230 is connected to the low-noise amplifier 14A. The selection terminal 231 among the plurality of selection terminals 231 and 232 is connected to the reception filter 15A. In addition, the selection terminal 232 among the plurality of selection terminals 231 and 232 is connected to the reception filter 15B.

The third switch 23 switches connection states between the common terminal 230 and the plurality of selection terminals 231 and 232. The third switch 23 is controlled by, for example, the signal processing circuit 301. The third switch 23 electrically connects the common terminal 230 to at least one of the plurality of selection terminals 231 and 232, according to a control signal from the RF signal processing circuit 302 of the signal processing circuit 301.

(2.12) Fourth Switch

The fourth switch 24 illustrated in FIG. 1 is a switch for switching signal paths (transmission path T2 and reception path R2) to be connected to the transmission and reception filter 17. That is, the fourth switch 24 switches the signal paths to be connected to the transmission and reception filter 17 between the transmission path T2 or the reception path R2. The fourth switch 24 has a common terminal 240 and a plurality of (two in the illustrated example) selection terminals 241 and 242. The common terminal 240 is connected to the transmission and reception filter 17. The selection terminal 241 among the plurality of selection terminals 241 and 242 is connected to the power amplifier 11B included in the transmission path T2. In addition, the selection terminal 242 among the plurality of selection terminals 241 and 242 is connected to the low-noise amplifier 14B included in the reception path R2.

The fourth switch 24 switches connection states between the common terminal 240 and the plurality of selection terminals 241 and 242. The fourth switch 24 is controlled by, for example, the signal processing circuit 301. The fourth switch 24 electrically connects the common terminal 240 to one of the plurality of selection terminals 241 and 242, according to a control signal from the RF signal processing circuit 302 of the signal processing circuit 301.

(2.13) Controller

The controller 20 controls the plurality of power amplifiers 11A and 11B, for example, according to a control signal from the signal processing circuit 301. The controller 20 is connected to the plurality of power amplifiers 11A and 11B. In addition, the controller 20 is connected to the signal processing circuit 301 with a plurality of (for example, four) control terminals 84 interposed therebetween. The plurality of control terminals 84 are terminals for inputting control signals from an external circuit (for example, the signal processing circuit 301) to the controller 20. The controller 20 controls the plurality of power amplifiers 11A and 11B based on the control signals acquired from the plurality of control terminals 84. The control signals acquired by the controller 20 from the plurality of control terminals 84 are digital signals. The number of control terminals 84 is, for example, four, and only one is illustrated in FIG. 1.

(2.14) External Connection Electrode

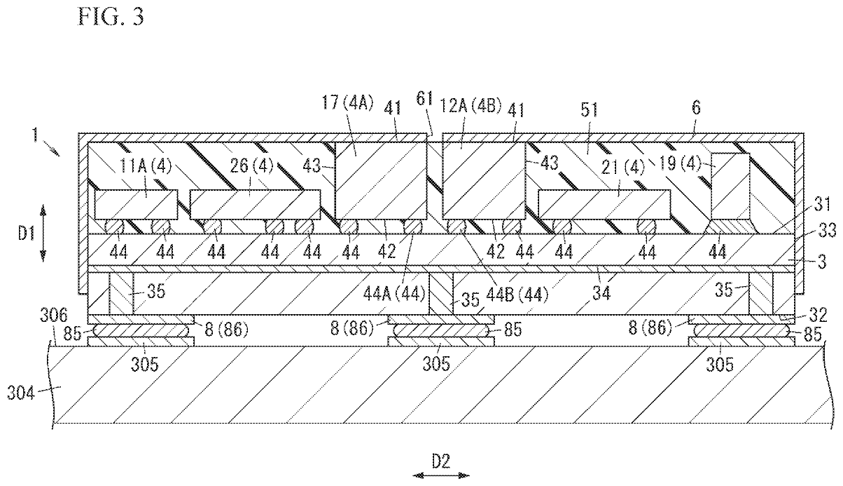

As illustrated in FIG. 1, the plurality of external connection electrodes 8 are terminals for electrically connecting to an external circuit (for example, the signal processing circuit 301). The plurality of external connection electrodes 8 include the antenna terminal 81, the plurality of signal input terminals 82A and 82B, the plurality of signal output terminals 83A and 83B, the plurality of control terminals 84, and a plurality of ground terminals 86 (see FIG. 3).

The antenna terminal 81 is connected to the antenna 310. In the high-frequency module 1, the antenna terminal 81 is connected to the first switch 21. In addition, the antenna terminal 81 is connected to the plurality of transmission filters 12A and 12B, the plurality of reception filters 15A and 15B, and the transmission and reception filter 17 with the first switch 21 interposed therebetween.

The plurality of signal input terminals 82A and 82B are terminals for inputting transmission signals from an external circuit (for example, the signal processing circuit 301) to the high-frequency module 1. In the high-frequency module 1, the signal input terminal 82A is connected to the power amplifier 11A. Further, in the high-frequency module 1, the signal input terminal 82B is connected to the power amplifier 11B.

The signal output terminal 83A is a terminal for outputting a reception signal from the low-noise amplifier 14A to an external circuit (for example, the signal processing circuit 301). The signal output terminal 83B is a terminal for outputting a reception signal from the low-noise amplifier 14B to an external circuit (for example, the signal processing circuit 301). In the high-frequency module 1, the signal output terminal 83A is connected to the low-noise amplifier 14A. Further, in the high-frequency module 1, the signal output terminal 83B is connected to the low-noise amplifier 14B.

The plurality of control terminals 84 are terminals for inputting control signals from an external circuit (for example, the signal processing circuit 301) to the high-frequency module 1. In the high-frequency module 1, the plurality of control terminals 84 are connected to the controller 20.

The plurality of ground terminals 86 are terminals which are electrically connected to a ground electrode of an external substrate 304 included in the communication device 300 and to which a ground potential is applied. In the high-frequency module 1, the plurality of ground terminals 86 are connected to a ground layer 34 of a mounting substrate 3.

### (3) Structure of High-Frequency Module

Hereinafter, a structure of the high-frequency module 1 according to Embodiment 1 will be described with reference to the drawings.

As illustrated in FIGS. 2 and 3, the high-frequency module 1 includes the mounting substrate 3, a plurality of (for example, 10) electronic components 4, and the plurality of external connection electrodes 8. The high-frequency module 1 further includes a resin layer 51 and a metal electrode layer 6.

The high-frequency module 1 can be electrically connected to the external substrate 304. The external substrate 304 corresponds to, for example, a mother substrate of the communication device 300, such as a mobile phone and a communication device. The fact that the high-frequency module 1 can be electrically connected to the external substrate 304 means not only a case where the high-frequency module 1 is directly mounted on the external substrate 304 but also a case where the high-frequency module 1 is indirectly mounted on the external substrate 304. The case where the high-frequency module 1 is indirectly mounted on the external substrate 304 is a case where the high-frequency module 1 is mounted on another high-frequency module mounted on the external substrate 304, or the like.

(3.1) Mounting Substrate

As illustrated in FIGS. 2 and 3, the mounting substrate 3 has a first main surface 31 and a second main surface 32. The first main surface 31 and the second main surface 32 face each other in a thickness direction D1 of the mounting substrate 3. When the high-frequency module 1 is provided on the external substrate 304, the second main surface 32 faces a main surface 306 of the external substrate 304 on the mounting substrate 3 side. The mounting substrate 3 is a single-side mounting substrate with the plurality of electronic components 4 mounted on the first main surface 31. In Embodiment 1, the thickness direction D1 of the mounting substrate 3 is a first direction (hereinafter, also referred to as a “first direction D1”).

The mounting substrate 3 is a multilayer substrate in which a plurality of dielectric layers are laminated. The mounting substrate 3 has a plurality of conductive layers and a plurality of via-conductors 35 (including through-electrodes). The plurality of conductive layers include the ground layer 34 at a ground potential. The plurality of via-conductors 35 are used for electrical connection between an element (including the electronic component 4 described above) mounted on the first main surface 31 and the conductive layer of the mounting substrate 3. In addition, the plurality of via-conductors 35 are used for electrical connection between the conductive layer of the mounting substrate 3 and the external connection electrode 8.

The plurality of electronic components 4 are disposed on the first main surface 31 of the mounting substrate 3. The plurality of electronic components 4 include a first electronic component 4A and a second electronic component 4B. The plurality of external connection electrodes 8 are disposed on the second main surface 32 of the mounting substrate 3.

(3.2) Electronic Component

As illustrated in FIGS. 2 and 3, the plurality of electronic components 4 are disposed on the first main surface 31 of the mounting substrate 3. In the example in FIG. 3, each of the electronic components 4 is mounted on the first main surface 31 of the mounting substrate 3. More specifically, each of the electronic components 4 is mounted on the first main surface 31 of the mounting substrate 3 with a plurality of connection portions 44 (for example, bumps) interposed therebetween. In each of the electronic components 4, a part of the electronic component 4 may be mounted on the first main surface 31 of the mounting substrate 3, and the rest part of the electronic component 4 may be built in the mounting substrate 3. In short, each of the electronic components 4 is disposed on the first main surface 31 side of the mounting substrate 3 than the second main surface 32, and has at least a part that is mounted on the first main surface 31.

Each of the plurality of electronic components 4 is any one of the plurality of power amplifiers 11A and 11B, the plurality of transmission filters 12A and 12B, the plurality of reception filters 15A and 15B, the plurality of low-noise amplifiers 14A and 14B, the transmission and reception filter 17, the plurality of output matching circuits 13A and 13B, the plurality of input matching circuits 16A and 16B, the plurality of matching circuits 18A to 18C, and 19, the first switch 21, the third switch 23, the fourth switch 24, and an IC chip 26. In addition, the first electronic component 4A is the transmission and reception filter 17, and the second electronic component 4B is the transmission filter 12A.

Each of the plurality of transmission filters 12A and 12B, the plurality of reception filters 15A and 15B, and the transmission and reception filter 17 is, for example, an acoustic wave filter including a plurality of series arm resonators and a plurality of parallel arm resonators. The acoustic wave filter is, for example, a surface acoustic wave (SAW) filter that uses a surface acoustic wave. Further, each of the plurality of transmission filters 12A and 12B, the plurality of reception filters 15A and 15B, and the transmission and reception filter 17 may include at least one of an inductor and a capacitor connected in series to any one of the plurality of series arm resonators, and include an inductor or a capacitor connected in series to any one of the plurality of parallel arm resonators.

The first electronic component 4A has a first signal terminal 44A. The first signal terminal 44A is an input terminal or an output terminal of the transmission and reception filter 17 as the first electronic component 4A. The second electronic component 4B has a second signal terminal 44B. The second signal terminal 44B is an input terminal or an output terminal of the transmission filter 12A as the second electronic component 4B. Each of the first signal terminal 44A and the second signal terminal 44B is, for example, a bump, as described above. The first electronic component 4A and the second electronic component 4B are disposed side by side along a second direction D2 orthogonal to (intersecting with) the first direction D1 which is a thickness direction of the mounting substrate 3. In the present specification, each of the first signal terminal and the second signal terminal is a radio frequency (RF) signal terminal through which a high-frequency signal passes.

The IC chip 26 includes the controller 20 and the second switch 22. In a plan view in the thickness direction D1 of the mounting substrate 3, an outer peripheral shape of the IC chip 26 is a quadrangle shape.

(3.3) External Connection Electrode

The plurality of external connection electrodes 8 are terminals for electrically connecting the mounting substrate 3 and the external substrate 304.

As illustrated in FIG. 3, the plurality of external connection electrodes 8 are disposed on the second main surface 32 of the mounting substrate 3. The plurality of external connection electrodes 8 correspond to the plurality of external connection electrodes 305 disposed on the main surface 306 of the external substrate 304 on a one-to-one basis. Each of the plurality of external connection electrodes 8 is connected to a corresponding external connection electrode 305 among the plurality of external connection electrodes 305 with a connection portion 85 (for example, a bump) interposed therebetween. The plurality of external connection electrodes 8 are columnar (for example, prismatic) electrodes provided on the second main surface 32 of the mounting substrate 3. Materials of the plurality of external connection electrodes 8 are, for example, metal (for example, copper, copper alloy, and the like). Each of the plurality of external connection electrodes 8 includes a base end portion joined to the second main surface 32 of the mounting substrate 3 and a tip portion opposite to the base end portion, in the thickness direction D1 of the mounting substrate 3. The tip portion of each of the plurality of external connection electrodes 8 may include, for example, a gold plating layer.

(3.4) Resin Layer

As illustrated in FIG. 3, the resin layer 51 is disposed on the first main surface 31 of the mounting substrate 3. The resin layer 51 covers the plurality of electronic components 4. Here, the resin layer 51 covers an outer peripheral surface 43 of each of the plurality of electronic components 4. In addition, the resin layer 51 covers a main surface 41 on a side opposite to the mounting substrate 3 side of each of the remaining electronic components 4 excluding the first electronic component 4A and the second electronic component 4B among the plurality of electronic components 4. The outer peripheral surface 43 of each of the plurality of electronic components 4 includes four side surfaces including the main surface 41 opposite to the mounting substrate 3 side and a main surface 42 on the mounting substrate 3 side, of the electronic component 4. The resin layer 51 includes a resin (for example, epoxy resin). The resin layer 51 may include a filler in addition to the resin.

(3.5) Metal Electrode Layer

As illustrated in FIG. 3, the metal electrode layer 6 covers the resin layer 51. The metal electrode layer 6 has conductivity. In the high-frequency module 1, the metal electrode layer 6 is a shield layer provided for the purpose of electromagnetic shielding inside and outside the high-frequency module 1. The metal electrode layer 6 has a multilayer structure in which a plurality of metal layers are laminated. Meanwhile, the present embodiment is not limited thereto, and may be one metal layer. The metal layer includes one type or a plurality of types of metals. The metal electrode layer 6 covers a main surface of the resin layer 51, which is opposite to the mounting substrate 3 side, an outer peripheral surface of the resin layer 51, and a part of an outer peripheral surface 33 of the mounting substrate 3. In addition, the metal electrode layer 6 covers the main surface 41 of each of the first electronic component 4A and the second electronic component 4B, which is opposite to the mounting substrate 3 side. The metal electrode layer 6 is in contact with at least a part of an outer peripheral surface of the ground layer 34 of the mounting substrate 3. Therefore, a potential of the metal electrode layer 6 can be set to be the same as a potential of the ground layer 34.

As illustrated in FIG. 3, the metal electrode layer 6 has a through-portion (slit) 61. The through-portion 61 is formed to penetrate the metal electrode layer 6 in the thickness direction D1 (up-down direction in FIG. 3) of the mounting substrate 3. The through-portion 61 is formed between the first electronic component 4A and the second electronic component 4B in the plan view in the thickness direction D1 of the mounting substrate 3. More specifically, the through-portion 61 is formed between the first signal terminal 44A of the first electronic component 4A and the second signal terminal 44B of the second electronic component 4B, in the plan view in the thickness direction D1 of the mounting substrate 3. Details of the through-portion 61 will be described in detail in a section “(6) Details of Metal Electrode Layer”.

### (4) Detailed Structure of Each Component of High-Frequency Module

(4.1) Mounting Substrate

The mounting substrate 3 illustrated in FIGS. 2 and 3 is, for example, a multilayer substrate including a plurality of dielectric layers and a plurality of conductive layers. The plurality of dielectric layers and the plurality of conductive layers are laminated in the thickness direction D1 of the mounting substrate 3. The plurality of conductive layers are formed in a predetermined pattern determined for each layer. Each of the plurality of conductive layers includes one or a plurality of conductor portions in one plane orthogonal to the thickness direction D1 of the mounting substrate 3. A material of each conductive layer is, for example, copper. The plurality of conductive layers include the ground layer 34. In the high-frequency module 1, the plurality of ground terminals 86 and the ground layer 34 are electrically connected to each other with the via-conductor 35 and the like of the mounting substrate 3 interposed therebetween. The mounting substrate 3 is, for example, a low temperature co-fired ceramics (LTCC) substrate. The mounting substrate 3 is not limited to the LTCC substrate, and may be, for example, a printed wiring board, a high temperature co-fired ceramics (HTCC) substrate, or a resin multilayer substrate.

Further, the mounting substrate 3 is not limited to the LTCC substrate, and may be, for example, a wiring structure. The wiring structure is, for example, a multilayer structure. The multilayer structure includes at least one insulating layer and at least one conductive layer. The insulating layer is formed in a predetermined pattern. In a case where the number of insulating layers is plural, the plurality of insulating layers are formed in a predetermined pattern determined for each layer. The conductive layer is formed in a predetermined pattern different from the predetermined pattern of the insulating layer. In a case where the number of conductive layers is plural, the plurality of conductive layers are formed in a predetermined pattern determined for each layer. The conductive layer may include one or a plurality of rewiring portions. In the wiring structure, a first surface of two surfaces facing each other in a thickness direction of the multilayer structure is the first main surface 31 of the mounting substrate 3, and a second surface is the second main surface 32 of the mounting substrate 3. The wiring structure may be, for example, an interposer. The interposer may be an interposer using a silicon substrate or may be a substrate having multiple layers.

The first main surface 31 and the second main surface 32 of the mounting substrate 3 are separated in the thickness direction D1 of the mounting substrate 3, and intersect with the thickness direction D1. The first main surface 31 of the mounting substrate 3 is, for example, orthogonal to the thickness direction D1 of the mounting substrate 3, and may include, for example, a side surface or the like of a conductor portion as a surface that is not orthogonal to the thickness direction D1. In addition, the second main surface 32 of the mounting substrate 3 is, for example, orthogonal to the thickness direction D1 of the mounting substrate 3, and may include, for example, a side surface or the like of a conductor portion as a surface that is not orthogonal to the thickness direction D1. Further, the first main surface 31 and the second main surface 32 of the mounting substrate 3 may be formed with a fine roughness portion, a recess portion, or a protruding portion.

(4.2) Filter

Detailed structures of the plurality of transmission filters 12A and 12B, the plurality of reception filters 15A and 15B, and the transmission and reception filter 17 illustrated in FIG. 1 will be described. In the following description, the transmission filters 12A and 12B, the reception filters 15A and 15B, and the transmission and reception filter 17 are referred to as filters without necessarily distinguishing between them.

The filter is a one-chip filter. Here, in the filter, for example, each of a plurality of series arm resonators and a plurality of parallel arm resonators is configured with an acoustic wave resonator. In this case, the filter includes, for example, a substrate, a piezoelectric body layer, and a plurality of interdigital transducer (IDT) electrodes. The substrate has a first surface and a second surface. The piezoelectric body layer is provided on the first surface of the substrate. The piezoelectric body layer is provided on a low velocity-of-sound film. The plurality of IDT electrodes are provided on the piezoelectric body layer. Here, the low velocity-of-sound film is directly or indirectly provided on the substrate. In addition, the piezoelectric body layer is directly or indirectly provided on the low velocity-of-sound film. In the low velocity-of-sound film, a velocity of sound of a bulk wave that propagates through the low velocity-of-sound film is lower than a velocity of sound of a bulk wave that propagates through the piezoelectric body layer. In the substrate, a velocity of sound of the bulk wave that propagates through the substrate is faster than a velocity of sound of an acoustic wave that propagates through the piezoelectric body layer. A material of the piezoelectric body layer is, for example, lithium tantalate. A material of the low velocity-of-sound film is, for example, silicon oxide. The substrate is, for example, a silicon substrate. A thickness of the piezoelectric body layer is, for example, equal to or less than 3.5λ, when λ is a wavelength of an acoustic wave determined by an electrode finger period of the IDT electrode. A thickness of the low velocity-of-sound film is, for example, equal to or less than 2.0λ.

The piezoelectric body layer may be formed with, for example, any one of lithium tantalate, lithium niobate, zinc oxide, aluminum nitride, or lead zirconate titanate (PZT). In addition, the low velocity-of-sound film may include at least one material selected from a group consisting of silicon oxide, glass, silicon oxynitride, tantalum oxide, and a compound obtained by adding fluorine, carbon, or boron to silicon oxide. In addition, the substrate may include at least one material selected from a group consisting of silicon, aluminum nitride, aluminum oxide, silicon carbide, silicon nitride, sapphire, lithium tantalate, lithium niobate, crystal, alumina, zirconia, cordierite, mullite, steatite, forsterite, magnesia, and diamond.

The filter further includes, for example, a spacer layer and a cover member. The spacer layer and the cover member are provided on the first surface of the substrate. The spacer layer surrounds the plurality of IDT electrodes, in a plan view in a thickness direction of the substrate. The spacer layer has a frame shape (rectangular frame shape), in the plan view in the thickness direction of the substrate. The spacer layer has electric insulation. The material of the spacer layer is, for example, an epoxy resin or a synthetic resin such as polyimide. The cover member has a flat plate shape. The cover member has an oblong shape in the plan view in the thickness direction of the substrate. Meanwhile, the cover member is not limited thereto, and may have, for example, a square shape. In the filter, an outer size of the cover member, an outer size of the spacer layer, and an outer size of the cover member are substantially the same, in the plan view in the thickness direction of the substrate. The cover member is disposed on the spacer layer to face the substrate in the thickness direction of the substrate. The cover member overlaps with the plurality of IDT electrodes in the thickness direction of the substrate, and is separated from the plurality of IDT electrodes in the thickness direction of the substrate. The cover member has electric insulation. A material of the cover member is, for example, an epoxy resin or a synthetic resin such as polyimide. The filter has a space surrounded by the substrate, the spacer layer, and the cover member. In the filter, the space contains a gas. The gas is, for example, air, an inert gas (for example, nitrogen gas), or the like. The plurality of terminals are exposed from the cover member. Each of the plurality of terminals is, for example, a bump. Each bump is, for example, a solder bump. Each bump is not limited to the solder bump, and may be, for example, a gold bump.

The filter may include, for example, a close contact layer interposed between the low velocity-of-sound film and the piezoelectric body layer. The close contact layer is made of, for example, a resin (epoxy resin and polyimide resin). Further, the filter may include a dielectric film either between the low velocity-of-sound film and the piezoelectric body layer, over the piezoelectric body layer, or under the low velocity-of-sound film.

Further, the filter may include, for example, a high velocity-of-sound film interposed between the substrate and the low velocity-of-sound film. Here, the high velocity-of-sound film is directly or indirectly provided on the substrate. The low velocity-of-sound film is directly or indirectly provided on the high velocity-of-sound film. The piezoelectric body layer is directly or indirectly provided on the low velocity-of-sound film. In the high velocity-of-sound film, a velocity of sound of a bulk wave that propagates through the high velocity-of-sound film is faster than a velocity of sound of an acoustic wave that propagates through the piezoelectric body layer. In the low velocity-of-sound film, a velocity of sound of a bulk wave that propagates through the low velocity-of-sound film is lower than a velocity of sound of a bulk wave that propagates through the piezoelectric body layer.

The high velocity-of-sound film is made of diamond-like carbon, aluminum nitride, aluminum oxide, silicon carbide, silicon nitride, silicon, sapphire, lithium tantalate, lithium niobate, a piezoelectric body such as crystal, various ceramics, such as alumina, zirconia, cordierite, mullite, steatite, and forsterite, magnesia, diamond, or a material having each of the above materials as a main component, and a material having a mixture of each of the above materials as a main component.

Regarding a thickness of the high velocity-of-sound film, since the high velocity-of-sound film has a function of confinement of acoustic waves in the piezoelectric body layer and the low velocity-of-sound film, the larger the thickness of the high velocity-of-sound film, the more suitable.

Each of the plurality of series arm resonators and the plurality of parallel arm resonators is not limited to the acoustic wave resonator described above, and may be, for example, a SAW resonator or a bulk acoustic wave (BAW) resonator. Here, the SAW resonator includes, for example, a piezoelectric substrate and an IDT electrode provided on the piezoelectric substrate. In a case where each of the plurality of series arm resonators and the plurality of parallel arm resonators is configured with the SAW resonator, the filter includes a plurality of IDT electrodes corresponding to the plurality of series arm resonators on a one-to-one basis on one piezoelectric substrate, and a plurality of IDT electrodes corresponding to the plurality of parallel arm resonators on a one-to-one basis. The piezoelectric substrate is, for example, a lithium tantalate substrate, a lithium niobate substrate, or the like.

(4.3) Power Amplifier

Each of the plurality of power amplifiers 11A and 11B illustrated in FIG. 1 is, for example, a one-chip IC including a substrate and an amplification function unit. The substrate has a first surface and a second surface that face each other. The substrate is, for example, a gallium arsenide substrate. The amplification function unit includes at least one transistor formed on the first surface of the substrate. The amplification function unit is a function unit having a function of amplifying a transmission signal in a predetermined frequency bandwidth. The transistor is, for example, a heterojunction bipolar transistor (HBT). In each of the plurality of power amplifiers 11A and 11B, a power supply voltage from a power supply circuit (not illustrated) is applied between a collector and an emitter of the HBT. Each of the plurality of power amplifiers 11A and 11B may include, for example, a DC cut capacitor in addition to the amplification function unit. Each of the plurality of power amplifiers 11A and 11B is provided with, for example, a flip-chip mounted on the first main surface 31 of the mounting substrate 3 such that the first surface of the substrate is on the first main surface 31 side of the mounting substrate 3. In the plan view in the thickness direction D1 of the mounting substrate 3, an outer peripheral shape of each of the plurality of power amplifiers 11A and 11B is a quadrangle shape.

(4.4) Low-Noise Amplifier

Each of the plurality of low-noise amplifiers 14A and 14B illustrated in FIG. 1 is, for example, a one-chip IC including a substrate and an amplification function unit. The substrate has a first surface and a second surface that face each other. The substrate is, for example, a silicon substrate. The amplification function unit is formed on the first surface of the substrate. The amplification function unit is a function unit having a function of amplifying a reception signal in a predetermined frequency bandwidth. Each of the plurality of low-noise amplifiers 14A and 14B is provided with, for example, a flip-chip mounted on the first main surface 31 of the mounting substrate 3 such that the first surface of the substrate is on the first main surface 31 side of the mounting substrate 3. In the plan view in the thickness direction D1 of the mounting substrate 3, an outer peripheral shape of each of the plurality of low-noise amplifiers 14A and 14B is a quadrangle shape.

### (5) Communication Device

As illustrated in FIG. 1, the communication device 300 includes the high-frequency module 1, the antenna 310, and the signal processing circuit 301.

(5.1) Antenna

The antenna 310 is connected to the antenna terminal 81 of the high-frequency module 1. The antenna 310 has a transmission function of emitting a transmission signal output from the high-frequency module 1 as a radio wave, and a reception function of receiving a reception signal from an outside as a radio wave and outputting the reception signal to the high-frequency module 1.

(5.2) Signal Processing Circuit

The signal processing circuit 301 includes the RF signal processing circuit 302 and a baseband signal processing circuit 303. The signal processing circuit 301 processes a signal passing through the high-frequency module 1. More specifically, the signal processing circuit 301 processes a transmission signal and a reception signal.

The RF signal processing circuit 302 is, for example, a radio frequency integrated circuit (RFIC). The RF signal processing circuit 302 performs signal processing on a high-frequency signal.

The RF signal processing circuit 302 performs signal processing, such as upconverting, on a high-frequency signal output from the baseband signal processing circuit 303, and outputs the high-frequency signal on which the signal processing is performed to the high-frequency module 1. Specifically, the RF signal processing circuit 302 performs signal processing, such as up-conversion, on a transmission signal output from the baseband signal processing circuit 303, and outputs the transmission signal on which the signal processing is performed to any one of the transmission paths T1 and T2 of the high-frequency module 1.

The RF signal processing circuit 302 performs signal processing, such as down-conversion, on a high-frequency signal output from the high-frequency module 1, and outputs the high-frequency signal on which the signal processing is performed to the baseband signal processing circuit 303. Specifically, the RF signal processing circuit 302 performs signal processing on a reception signal output from any one of the reception path R1 or R2 of the high-frequency module 1, and outputs the reception signal on which the signal processing is performed to the baseband signal processing circuit 303.

The baseband signal processing circuit 303 is, for example, a baseband integrated circuit (BBIC). The baseband signal processing circuit 303 performs predetermined signal processing on a transmission signal from an outside of the signal processing circuit 301. The reception signal processed by the baseband signal processing circuit 303 is used, for example, as an image signal as an image signal for an image display or used as an audio signal for a call.

Further, the RF signal processing circuit 302 also has a function as a control unit that controls connection of each of the first switch 21, the second switch 22, the third switch 23, and the fourth switch 24 included in the high-frequency module 1, based on transmission and reception of the high-frequency signals (transmission signal and reception signal). Specifically, the RF signal processing circuit 302 switches the connections of each of the first switch 21, the second switch 22, the third switch 23, and the fourth switch 24 of the high-frequency module 1, by a control signal (not illustrated). The control unit may be provided outside the RF signal processing circuit 302, and may be provided in the high-frequency module 1 or the baseband signal processing circuit 303, for example.

### (6) Details of Metal Electrode Layer

Hereinafter, details of the metal electrode layer 6 will be described with reference to the drawings.

As described above, the metal electrode layer 6 covers the main surface of the resin layer 51, which is opposite to the mounting substrate 3 side, the outer peripheral surface of the resin layer 51, and the part of the outer peripheral surface 33 of the mounting substrate 3. In addition, the metal electrode layer 6 covers the main surface 41 of each of the first electronic component 4A and the second electronic component 4B, which is opposite to the mounting substrate 3 side. In addition, in the high-frequency module 1 according to Embodiment 1, the main surface 41 opposite to the mounting substrate 3 side in each of the first electronic component 4A and the second electronic component 4B is in contact with the metal electrode layer 6. Therefore, in the high-frequency module 1 according to Embodiment 1, heat generated in each of the first electronic component 4A and the second electronic component 4B can be emitted to the external substrate 304 through the metal electrode layer 6, the ground layer 34 (of the mounting substrate 3), the via-conductor 35, and the external connection electrode 8.

Here, in the high-frequency module 1 according to Embodiment 1, as illustrated in FIGS. 2 and 3, the metal electrode layer 6 has the through-portion 61. The through-portion 61 is a through-hole formed to penetrate through the metal electrode layer 6 in the thickness direction D1 of the mounting substrate 3. Therefore, a part of the main surface of the resin layer 51 opposite to the mounting substrate 3 side is exposed to the outside through the through-portion 61 (see FIG. 3). A cross-sectional shape of the through-portion 61 has a rectangular shape. Further, as illustrated in FIG. 2, a length L2 of the through-portion 61 in a third direction D3, which is a direction orthogonal to (intersecting with) the thickness direction D1 of the mounting substrate 3, is longer than a length L11 of the first electronic component 4A and a length L12 of the second electronic component 4B in the third direction D3, and longer than a length L3 of the mounting substrate 3 in the third direction D3. That is, in the high-frequency module 1 according to Embodiment 1, the through-portion 61 is formed over a total length of the mounting substrate 3 in the third direction D3, which is one direction intersecting with the thickness direction D1 of the mounting substrate 3.

Further, in the high-frequency module 1 according to Embodiment 1, as illustrated in FIG. 3, the through-portion 61 is located between the first signal terminal 44A of the first electronic component 4A and the second signal terminal 44B of the second electronic component 4B, in the plan view in the thickness direction D1 of the mounting substrate 3. The first signal terminal 44A is, for example, an input terminal or an output terminal of the transmission and reception filter 17 as the first electronic component 4A. The second signal terminal 44B is, for example, an input terminal or an output terminal of the transmission filter 12A as the second electronic component 4B. In this manner, by providing the through-portion 61 between the first signal terminal 44A of the first electronic component 4A and the second signal terminal 44B of the second electronic component 4B, it is possible to reduce the transmission of a signal passing through one of the first signal terminal 44A and the second signal terminal 44B to the other of the first signal terminal 44A and the second signal terminal 44B through the metal electrode layer 6. That is, with the high-frequency module 1 according to Embodiment 1, it is possible to reduce a decrease in isolation between the first signal terminal 44A and the second signal terminal 44B.

### (7) Method of Manufacturing High-Frequency Module

Next, a method of manufacturing the high-frequency module 1 according to Embodiment 1 will be briefly described.

The method of manufacturing the high-frequency module 1 includes, for example, a first step, a second step, a third step, a fourth step, and a fifth step.

The first step is a step of disposing the plurality of electronic components 4 on the first main surface 31 of the mounting substrate 3. The second step is a step of forming a resin material layer that covers the plurality of electronic components 4 and becomes a base of the resin layer 51 on the first main surface 31 side of the mounting substrate 3. The third step is a step of grinding the resin material layer from a main surface of the resin material layer opposite to the mounting substrate 3 side to expose a surface (upper surface) of each of the first electronic component 4A and the second electronic component 4B, and then grinding the resin material layer, the first electronic component 4A, and the second electronic component 4B to form the resin layer 51 and thin the first electronic component 4A and the second electronic component 4B. The fourth step is a step of forming the main surface of the resin layer 51 opposite to the mounting substrate 3 side and the metal electrode layer 6 in contact with the main surface 41 of the first electronic component 4A and the main surface 41 of the second electronic component 4B by, for example, a sputtering method, an evaporation method, or a printing method. The fifth step is, for example, a process of forming the through-portion 61 in the metal electrode layer 6 by using a laser.

### (8) Effect

In the high-frequency module 1 according to Embodiment 1, the through-portion 61 of the metal electrode layer 6 is provided between the first signal terminal 44A of the first electronic component 4A and the second signal terminal 44B of the second electronic component 4B, in the plan view in the thickness direction D1 of the mounting substrate 3. Therefore, it is possible to reduce a decrease in isolation between the first signal terminal 44A and the second signal terminal 44B, as compared with a case where the through-portion 61 is not provided between the first signal terminal 44A of the first electronic component 4A and the second signal terminal 44B of the second electronic component 4B.

In the high-frequency module 1 according to Embodiment 1, the first electronic component 4A and the second electronic component 4B are high-frequency components provided in the transmission paths T1 and T2. The main surface 41 of the first electronic component 4A opposite to the mounting substrate 3 side and the main surface 41 of the second electronic component 4B opposite to the mounting substrate 3 side are in contact with the metal electrode layer 6. Therefore, the heat generated in each of the first electronic component 4A and the second electronic component 4B can be emitted through the metal electrode layer 6.

In the high-frequency module 1 according to Embodiment 1, the length L2 of the through-portion 61 in the third direction (one direction) D3 is longer than the length L11 of the first electronic component 4A and the length L12 of the second electronic component 4B in the third direction D3, and longer than the total length L3 of the mounting substrate 3 in the third direction D3. Therefore, as compared with a case where the length L2 of the through-portion 61 in the third direction D3 is shorter than the length L11 of the first electronic component 4A and the length L12 of the second electronic component 4B in the third direction D3, it is possible to more effectively reduce the decrease in isolation between the first signal terminal 44A of the first electronic component 4A and the second signal terminal 44B of the second electronic component 4B.

### Embodiment 2

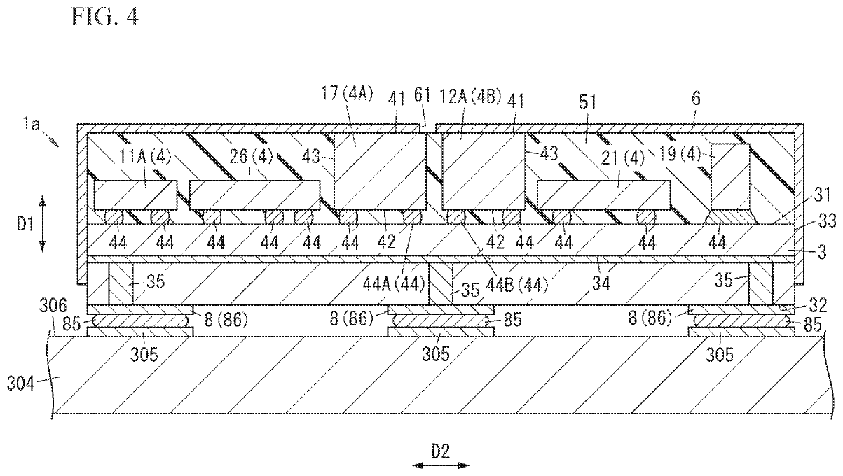

As illustrated in FIG. 4, a high-frequency module 1a according to Embodiment 2 is different from the high-frequency module 1 according to Embodiment 1 (see FIG. 3) in that a part of the main surface 41 of the first electronic component 4A opposite to the mounting substrate 3 side is formed to be exposed by the through-portion 61 of the metal electrode layer 6.

### (1) Configuration

As illustrated in FIG. 4, the high-frequency module 1a according to Embodiment 2 includes the mounting substrate 3, the plurality of electronic components 4, and the plurality of external connection electrodes 8. The high-frequency module 1a further includes the resin layer 51 and the metal electrode layer 6. Regarding the high-frequency module 1a according to Embodiment 2, the same components as the high-frequency module 1 according to Embodiment 1 are attached with the same reference numerals, and the description thereof will be omitted.

In the high-frequency module 1a according to Embodiment 2, the metal electrode layer 6 has the through-portion 61, in the same manner as the high-frequency module 1 according to Embodiment 1. A cross-sectional shape of the through-portion 61 has a rectangular shape. Further, the through-portion 61 is formed over a total length of the mounting substrate 3 in a third direction (a direction orthogonal to the first direction D1 and the second direction D2) which is a direction orthogonal to (intersecting with) the thickness direction D1 of the mounting substrate 3. Further, as illustrated in FIG. 4, the through-portion 61 is formed to expose a part of the main surface 41 of the first electronic component 4A opposite to the mounting substrate 3 side. In the high-frequency module 1a according to Embodiment 2, the through-portion 61 is also located between the first signal terminal 44A of the first electronic component 4A and the second signal terminal 44B of the second electronic component 4B, in the plan view in the thickness direction D1 of the mounting substrate 3.

### (2) Effect

In the same manner as the high-frequency module 1 according to Embodiment 1, also in the high-frequency module 1a according to Embodiment 2, the through-portion 61 of the metal electrode layer 6 is located between the first signal terminal 44A of the first electronic component 4A and the second signal terminal 44B of the second electronic component 4B, in the plan view in the thickness direction D1 of the mounting substrate 3. Therefore, it is possible to reduce a decrease in isolation between the first signal terminal 44A and the second signal terminal 44B.

### Embodiment 3

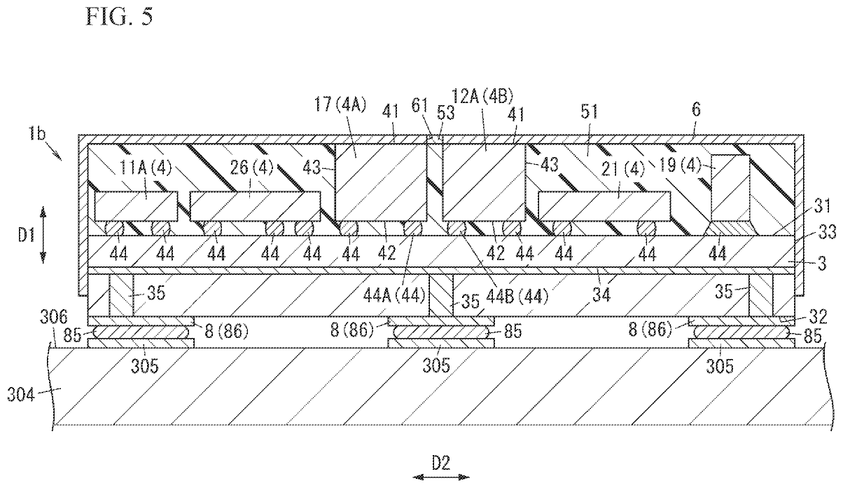

As illustrated in FIG. 5, a high-frequency module 1b according to Embodiment 3 is different from the high-frequency module 1 according to Embodiment 1 (see FIG. 3) in that a resin member 53 is disposed at the through-portion 61 of the metal electrode layer 6.

### (1) Configuration

As illustrated in FIG. 5, the high-frequency module 1b according to Embodiment 3 includes the mounting substrate 3, the plurality of electronic components 4, and the plurality of external connection electrodes 8. The high-frequency module 1b further includes the resin layer 51 and the metal electrode layer 6. Regarding the high-frequency module 1b according to Embodiment 3, the same components as the high-frequency module 1 according to Embodiment 1 are attached with the same reference numerals, and the description thereof will be omitted.

In the high-frequency module 1b according to Embodiment 3, the metal electrode layer 6 has the through-portion 61, in the same manner as the high-frequency module 1 according to Embodiment 1. A cross-sectional shape of the through-portion 61 has a rectangular shape. Further, the through-portion 61 is formed over a total length of the mounting substrate 3 in a third direction (a direction orthogonal to the first direction D1 and the second direction D2) which is a direction orthogonal to (intersecting with) the thickness direction D1 of the mounting substrate 3. In the high-frequency module 1b according to Embodiment 3, as illustrated in FIG. 5, the resin member 53 is disposed at the through-portion 61. The resin member 53 is disposed, for example, over a total length of the through-portion 61 in the third direction D3, and may be disposed at a part of the through-portion 61. That is, in the high-frequency module 1b according to Embodiment 3, a part of a main surface of the resin layer 51 opposite to the mounting substrate 3 side corresponding to the through-portion 61 is not exposed to an outside with the through-portion 61 interposed therebetween. A material of the resin member 53 may be the same material as the resin layer 51 or may be a different material.

### (2) Effect

In the same manner as the high-frequency module 1 according to Embodiment 1, also in the high-frequency module 1b according to Embodiment 3, the through-portion 61 of the metal electrode layer 6 is located between the first signal terminal 44A of the first electronic component 4A and the second signal terminal 44B of the second electronic component 4B, in the plan view in the thickness direction D1 of the mounting substrate 3. Therefore, it is possible to reduce a decrease in isolation between the first signal terminal 44A and the second signal terminal 44B.

### Embodiment 4

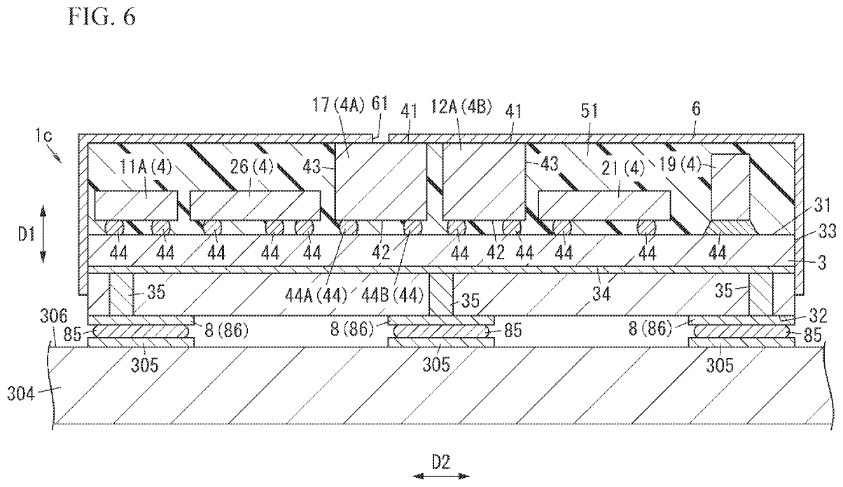

As illustrated in FIG. 6, a high-frequency module 1c according to Embodiment 4 is different from the high-frequency module 1 according to Embodiment 1 (see FIG. 3) in that the through-portion 61 is formed to overlap with the first electronic component 4A in the plan view in the thickness direction D1 of the mounting substrate 3.

### (1) Configuration

As illustrated in FIG. 6, the high-frequency module 1c according to Embodiment 4 includes the mounting substrate 3, the plurality of electronic components 4, and the plurality of external connection electrodes 8. The high-frequency module 1c further includes the resin layer 51 and the metal electrode layer 6. Regarding the high-frequency module 1c according to Embodiment 4, the same components as the high-frequency module 1 according to Embodiment 1 are attached with the same reference numerals, and the description thereof will be omitted.

In the high-frequency module 1c according to Embodiment 4, the metal electrode layer 6 has the through-portion 61, in the same manner as the high-frequency module 1 according to Embodiment 1. A cross-sectional shape of the through-portion 61 has a rectangular shape. Further, the through-portion 61 is formed over a total length of the mounting substrate 3 in a third direction (a direction orthogonal to the first direction D1 and the second direction D2) which is a direction orthogonal to (intersecting with) the thickness direction D1 of the mounting substrate 3. Further, as illustrated in FIG. 6, the through-portion 61 overlaps with the first electronic component 4A in the plan view in the thickness direction D1 of the mounting substrate 3. Therefore, a part of the main surface 41 of the first electronic component 4A opposite to the mounting substrate 3 side is exposed to an outside through the through-portion 61. Further, as illustrated in FIG. 6, the through-portion 61 is provided between the first signal terminal 44A and the second signal terminal 44B, in the plan view in the thickness direction D1 of the mounting substrate 3. The first signal terminal 44A is, for example, an input terminal of the transmission and reception filter 17 as the first electronic component 4A. The second signal terminal 44B is, for example, an output terminal of the transmission and reception filter 17 as the first electronic component 4A. The first signal terminal 44A may be the output terminal of the transmission and reception filter 17, and the second signal terminal 44B may be the input terminal of the transmission and reception filter 17.

### (2) Effect

In the same manner as the high-frequency module 1 according to Embodiment 1, also in the high-frequency module 1c according to Embodiment 4, the through-portion 61 of the metal electrode layer 6 is located between the first signal terminal 44A and the second signal terminal 44B, in the plan view in the thickness direction D1 of the mounting substrate 3. Therefore, it is possible to reduce a decrease in isolation between the first signal terminal 44A and the second signal terminal 44B.

### Embodiment 5

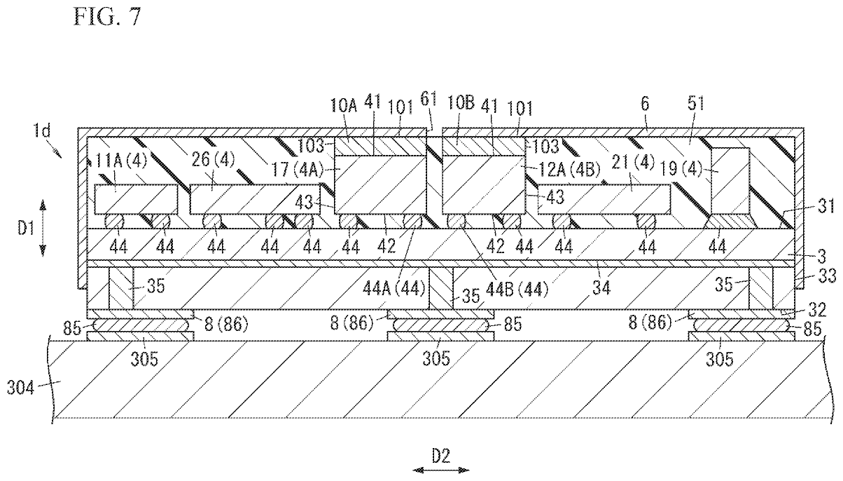

As illustrated in FIG. 7, a high-frequency module 1d according to Embodiment 5 is different from the high-frequency module 1 according to Embodiment 1 (see FIG. 3) in that a first metal member 10A is disposed on the main surface 41 of the first electronic component 4A, which is opposite to the mounting substrate 3 side. Further, the high-frequency module 1d is different from the high-frequency module 1 according to Embodiment 1 in that a second metal member 10B is disposed on the main surface 41 of the second electronic component 4B, which is opposite to the mounting substrate 3 side.

### (1) Configuration

As illustrated in FIG. 7, the high-frequency module 1d according to Embodiment 5 includes the mounting substrate 3, the plurality of electronic components 4, and the plurality of external connection electrodes 8. The high-frequency module 1d further includes the resin layer 51 and the metal electrode layer 6. The high-frequency module 1d further includes the first metal member 10A and the second metal member 10B. Regarding the high-frequency module 1d according to Embodiment 5, the same components as the high-frequency module 1 according to Embodiment 1 are attached with the same reference numerals, and the description thereof will be omitted.

As illustrated in FIG. 7, in the high-frequency module 1d according to Embodiment 5, the first metal member 10A is disposed on the main surface 41 of the first electronic component 4A, which is opposite to the mounting substrate 3 side. Further, in the high-frequency module 1d, the second metal member 10B is disposed on the main surface 41 of the second electronic component 4B, which is opposite to the mounting substrate 3 side. Each of the first metal member 10A and the second metal member 10B has a quadrangle shape in the plan view in the thickness direction D1 of the mounting substrate 3, and the shape is not limited to the quadrangle shape. In addition, the first metal member 10A has the same size as the first electronic component 4A in the plan view in the thickness direction D1 of the mounting substrate 3, and may be larger or smaller than the first electronic component 4A. In addition, the second metal member 10B has the same size as the second electronic component 4B in the plan view in the thickness direction D1 of the mounting substrate 3, and may be larger or smaller than the second electronic component 4B. Materials of the first metal member 10A and the second metal member 10B are, for example, copper or a copper alloy. The first metal member 10A may be joined to or just in contact with the main surface 41 of the first electronic component 4A opposite to the mounting substrate 3 side. In addition, the second metal member 10B may be joined to or just in contact with the main surface 41 of the second electronic component 4B opposite to the mounting substrate 3 side. The material of the first metal member 10A and the material of the second metal member 10B may be the same, and may be different from each other.

In the high-frequency module 1d according to Embodiment 5, as illustrated in FIG. 7, a main surface 101 of the first metal member 10A opposite to the mounting substrate 3 side is in contact with the metal electrode layer 6. Therefore, the first electronic component 4A is connected to the metal electrode layer 6 with the first metal member 10A interposed therebetween. As a result, heat generated in the first electronic component 4A can be emitted to the metal electrode layer 6 through the first metal member 10A. Further, in the high-frequency module 1d, as illustrated in FIG. 7, the main surface 101 of the second metal member 10B opposite to the mounting substrate 3 side is in contact with the metal electrode layer 6. Therefore, the second electronic component 4B is connected to the metal electrode layer 6 with the second metal member 10B interposed therebetween. As a result, heat generated in the second electronic component 4B can be emitted to the metal electrode layer 6 through the second metal member 10B.

In the high-frequency module 1d according to Embodiment 5, the metal electrode layer 6 has the through-portion 61, in the same manner as the high-frequency module 1 according to Embodiment 1. A cross-sectional shape of the through-portion 61 has a rectangular shape. Further, the through-portion 61 is formed over a total length of the mounting substrate 3 in a third direction (a direction orthogonal to the first direction D1 and the second direction D2) which is a direction orthogonal to (intersecting with) the thickness direction D1 of the mounting substrate 3. Further, as illustrated in FIG. 7, the through-portion 61 is provided between the first signal terminal 44A of the first electronic component 4A and the second signal terminal 44B of the second electronic component 4B, in the plan view in the thickness direction D1 of the mounting substrate 3. The first signal terminal 44A is, for example, an input terminal or an output terminal of the transmission and reception filter 17 as the first electronic component 4A. The second signal terminal 44B is, for example, an input terminal or an output terminal of the transmission filter 12A as the second electronic component 4B.

### (2) Effect

In the same manner as the high-frequency module 1 according to Embodiment 1, also in the high-frequency module 1d according to Embodiment 5, the through-portion 61 of the metal electrode layer 6 is located between the first signal terminal 44A and the second signal terminal 44B, in the plan view in the thickness direction D1 of the mounting substrate 3. Therefore, it is possible to reduce a decrease in isolation between the first signal terminal 44A and the second signal terminal 44B.

### Embodiment 6

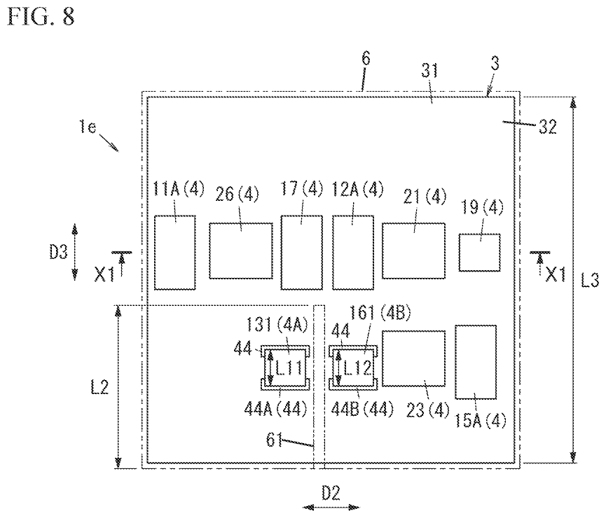

As illustrated in FIG. 8, a high-frequency module 1e according to Embodiment 6 is different from the high-frequency module 1 according to Embodiment 1 (see FIG. 3) in that the through-portion 61 is formed between a first inductor 131 and a second inductor 161 in the plan view in the thickness direction D1 of the mounting substrate 3.

### (1) Configuration

As illustrated in FIG. 8, the high-frequency module 1e according to Embodiment 6 includes the mounting substrate 3, the plurality of electronic components 4, and the plurality of external connection electrodes (not illustrated). The high-frequency module 1e further includes a resin layer (not illustrated) and the metal electrode layer 6. Regarding the high-frequency module 1e according to Embodiment 6, the same components as the high-frequency module 1 according to Embodiment 1 are attached with the same reference numerals, and the description thereof will be omitted.

In the high-frequency module 1e according to Embodiment 6, the metal electrode layer 6 has the through-portion 61, in the same manner as the high-frequency module 1 according to Embodiment 1. A cross-sectional shape of the through-portion 61 has a rectangular shape. In the high-frequency module 1e according to Embodiment 6, as illustrated in FIG. 8, the through-portion 61 is formed between the first inductor 131 and the second inductor 161, in the plan view in the thickness direction of the mounting substrate 3 (a direction orthogonal to the second direction D2 and the third direction D3). The length L2 of the through-portion 61 in the third direction D3 is longer than the length L11 of the first electronic component 4A in the third direction D3, and longer than the length L12 of the second electronic component 4B in the third direction D3. Further, the length L2 of the through-portion 61 in the third direction D3 is shorter than the length (total length) L3 of the mounting substrate 3 in the third direction D3.

The first inductor 131 is, for example, an inductor constituting the output matching circuit 13A, and corresponds to the first electronic component 4A. That is, the first inductor 131 is an inductor provided in a signal path (transmission path T1) through which a transmission signal passes. The first inductor 131 is connected, for example, between the transmission path T1 and a ground. The first electronic component 4A constituting the first inductor 131 is mounted on the first main surface 31 of the mounting substrate 3 with the plurality of connection portions 44 interposed therebetween. In the high-frequency module 1e according to Embodiment 6, one of the plurality of connection portions 44 is the first signal terminal 44A, and the first signal terminal 44A is a terminal connected to the transmission path T1.

The second inductor 161 is, for example, an inductor constituting the input matching circuit 16A, and corresponds to the second electronic component 4B. That is, the second inductor 161 is an inductor provided in a signal path (reception path R1) through which a reception signal passes. The second inductor 161 is connected, for example, between the reception path R1 and the ground. The second electronic component 4B constituting the second inductor 161 is mounted on the first main surface 31 of the mounting substrate 3 with the plurality of connection portions 44 interposed therebetween. In the high-frequency module 1e according to Embodiment 6, one of the plurality of connection portions 44 is the second signal terminal 44B, and the second signal terminal 44B is a terminal connected to the reception path R1.

### (2) Effect

In the same manner as the high-frequency module 1 according to Embodiment 1, also in the high-frequency module 1e according to Embodiment 6, the through-portion 61 of the metal electrode layer 6 is located between the first signal terminal 44A and the second signal terminal 44B, in the plan view in the thickness direction D1 of the mounting substrate 3. Therefore, it is possible to reduce a decrease in isolation between the first signal terminal 44A and the second signal terminal 44B.

### Embodiment 7

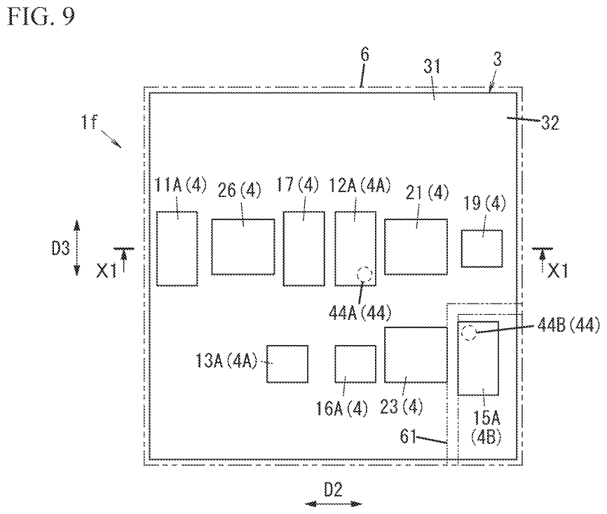

As illustrated in FIG. 9, a high-frequency module if according to Embodiment 7 is different from the high-frequency module 1 according to Embodiment 1 (see FIG. 3) in that the through-portion 61 is formed in an L shape in the plan view in the thickness direction D1 of the mounting substrate 3.

### (1) Configuration

As illustrated in FIG. 9, the high-frequency module if according to Embodiment 7 includes the mounting substrate 3, the plurality of electronic components 4, and the plurality of external connection electrodes (not illustrated). The high-frequency module if further includes a resin layer (not illustrated) and the metal electrode layer 6. Regarding the high-frequency module if according to Embodiment 7, the same components as the high-frequency module 1 according to Embodiment 1 are attached with the same reference numerals, and the description thereof will be omitted.

In the high-frequency module if according to Embodiment 7, the metal electrode layer 6 has the through-portion 61, in the same manner as the high-frequency module 1 according to Embodiment 1. A cross-sectional shape of the through-portion 61 has a rectangular shape. Further, the through-portion 61 is formed in an L shape in the plan view in the thickness direction D1 of the mounting substrate 3. In the high-frequency module if according to Embodiment 7, as illustrated in FIG. 9, the through-portion 61 is formed to surround the second electronic component 4B in the plan view in the thickness direction D1 of the mounting substrate 3. The second electronic component 4B is, for example, the reception filter 15A. Further, the first electronic component 4A is, for example, the transmission filter 12A.

The first electronic component 4A has a first signal terminal 44A. The first signal terminal 44A is an input terminal or an output terminal of the transmission filter 12A as the first electronic component 4A. The second electronic component 4B has the second signal terminal 44B. The second signal terminal 44B is an input terminal or an output terminal of the reception filter 15A as the second electronic component 4B. Each of the first signal terminal 44A and the second signal terminal 44B is, for example, a bump. In the high-frequency module if according to Embodiment 7, the through-portion 61 is located between the first signal terminal 44A and the second signal terminal 44B in the plan view in the thickness direction D1 of the mounting substrate 3.

### (2) Effect

In the same manner as the high-frequency module 1 according to Embodiment 1, also in the high-frequency module if according to Embodiment 7, the through-portion 61 of the metal electrode layer 6 is located between the first signal terminal 44A and the second signal terminal 44B, in the plan view in the thickness direction D1 of the mounting substrate 3. Therefore, it is possible to reduce a decrease in isolation between the first signal terminal 44A and the second signal terminal 44B.

### Embodiment 8

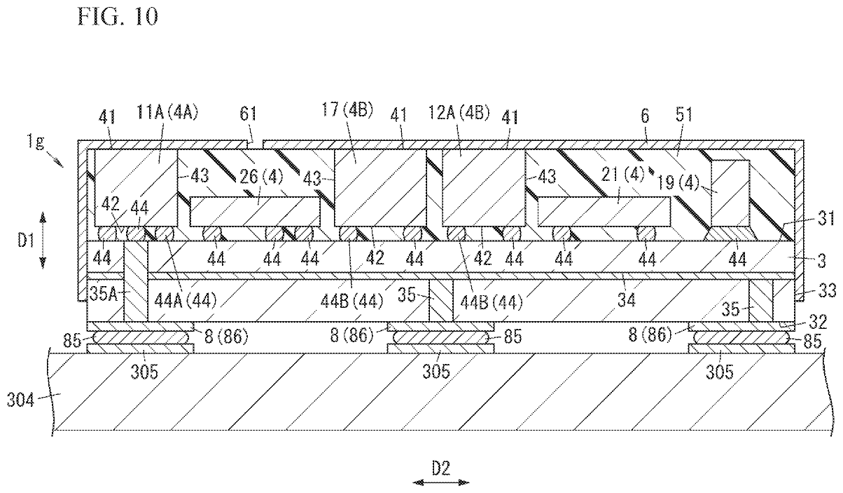

As illustrated in FIG. 10, a high-frequency module 1g according to Embodiment 8 is different from the high-frequency module 1 according to Embodiment 1 (see FIG. 3) in that the power amplifier 11A provided in the transmission path T1 is the first electronic component 4A. Further, the high-frequency module 1g is different from the high-frequency module 1 according to Embodiment 1 in that the transmission and reception filter 17 provided on the transmission path T2 is the second electronic component 4B.

### (1) Configuration

As illustrated in FIG. 10, the high-frequency module 1g according to Embodiment 8 includes the mounting substrate 3, the plurality of electronic components 4, and the plurality of external connection electrodes 8. The high-frequency module 1g further includes the resin layer 51 and the metal electrode layer 6. Regarding the high-frequency module 1g according to Embodiment 8, the same components as the high-frequency module 1 according to Embodiment 1 are attached with the same reference numerals, and the description thereof will be omitted.

In the high-frequency module 1g according to Embodiment 8, the metal electrode layer 6 has the through-portion 61, in the same manner as the high-frequency module 1 according to Embodiment 1. A cross-sectional shape of the through-portion 61 has a rectangular shape. Further, the through-portion 61 is formed over a total length of the mounting substrate 3 in a third direction (a direction orthogonal to the first direction D1 and the second direction D2) which is a direction orthogonal to (intersecting with) the thickness direction D1 of the mounting substrate 3. In the high-frequency module 1g according to Embodiment 8, as illustrated in FIG. 10, the through-portion 61 is located between the first electronic component 4A and the plurality of (two in the illustrated example) second electronic components 4B in the plan view in the thickness direction D1 of the mounting substrate 3.

The first electronic component 4A is, for example, the power amplifier 11A provided on the transmission path T1. The first electronic component 4A has the first signal terminal 44A. The first signal terminal 44A is, for example, a bump. The first signal terminal 44A is an input terminal or an output terminal of the power amplifier 11A as the first electronic component 4A. The main surface 41 of the first electronic component 4A opposite to the mounting substrate 3 side is in contact with the metal electrode layer 6. Therefore, heat generated in the first electronic component 4A can be emitted through the metal electrode layer 6.

Here, the first electronic component 4A is the power amplifier 11A as described above. In a case where a substrate constituting the power amplifier 11A is a gallium arsenide substrate, as in the high-frequency module 1 according to Embodiment 1, it is difficult to cut a surface of the first electronic component 4A opposite to the mounting substrate 3 side. Therefore, the substrate constituting the power amplifier 11A can be a silicon substrate or a substrate obtained by bonding the silicon substrate and the gallium arsenide substrate.

Each of the plurality of second electronic components 4B is, for example, the transmission and reception filter 17 provided on the transmission path T2 or the transmission filter 12A provided on the transmission path T1. Each of the plurality of second electronic components 4B has the second signal terminal 44B. The second signal terminal 44B is, for example, a bump. In a case where the second electronic component 4B is the transmission and reception filter 17, the second signal terminal 44B is an input terminal or an output terminal of the transmission and reception filter 17. In a case where the second electronic component 4B is the transmission filter 12A, the second signal terminal 44B is an input terminal or an output terminal of the transmission filter 12A. The main surface 41 opposite to the mounting substrate 3 side in each of the plurality of second electronic components 4B is in contact with the metal electrode layer 6. Therefore, heat generated in each of the second electronic components 4B can be emitted through the metal electrode layer 6.

Further, in the high-frequency module 1g according to Embodiment 8, the mounting substrate 3 has a through-electrode 35A. The through-electrode 35A penetrates through the mounting substrate 3 in the thickness direction D1 of the mounting substrate 3. The through-electrode 35A connects the connection portion 44 of the first electronic component 4A and the ground terminal 86. Therefore, the power amplifier 11A as the first electronic component 4A can also emit the heat generated in the power amplifier 11A to the external substrate 304 through the through-electrode 35A.

### (2) Effect

In the same manner as the high-frequency module 1 according to Embodiment 1, also in the high-frequency module 1g according to Embodiment 8, the through-portion 61 of the metal electrode layer 6 is located between the first signal terminal 44A and the second signal terminal 44B, in the plan view in the thickness direction D1 of the mounting substrate 3. Therefore, it is possible to reduce a decrease in isolation between the first signal terminal 44A and the second signal terminal 44B.

### Embodiment 9

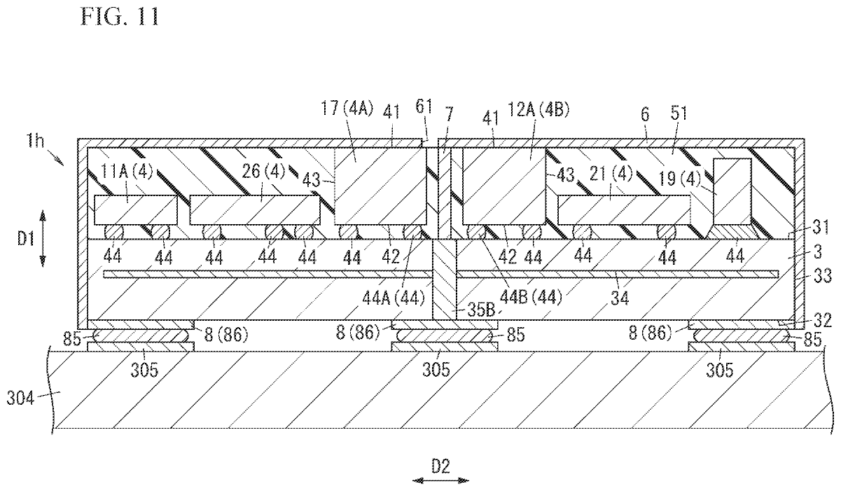

As illustrated in FIG. 11, a high-frequency module 1h according to Embodiment 9 is different from the high-frequency module 1 according to Embodiment 1 (see FIG. 3) in that a metal electrode member 7 is disposed between the first electronic component 4A and the second electronic component 4B.

### (1) Configuration

As illustrated in FIG. 11, the high-frequency module 1h according to Embodiment 9 includes the mounting substrate 3, the plurality of electronic components 4, and the plurality of external connection electrodes 8. The high-frequency module 1h further includes the resin layer 51 and the metal electrode layer 6. The high-frequency module 1h further includes the metal electrode member 7. Regarding the high-frequency module 1h according to Embodiment 9, the same components as the high-frequency module 1 according to Embodiment 1 are attached with the same reference numerals, and the description thereof will be omitted.

In the high-frequency module 1h according to Embodiment 9, the metal electrode layer 6 has the through-portion 61, in the same manner as the high-frequency module 1 according to Embodiment 1. A cross-sectional shape of the through-portion 61 has a rectangular shape. Further, the through-portion 61 is formed over a total length of the mounting substrate 3 in a third direction (a direction orthogonal to the first direction D1 and the second direction D2) which is a direction orthogonal to (intersecting with) the thickness direction D1 of the mounting substrate 3. In the high-frequency module 1h according to Embodiment 9, as illustrated in FIG. 11, the through-portion 61 is located between the first electronic component 4A and the second electronic component 4B in the plan view in the thickness direction D1 of the mounting substrate 3. Further, in the high-frequency module 1h, a part of the main surface 41 of the first electronic component 4A opposite to the mounting substrate 3 side and a part of a main surface of the resin layer 51 opposite to the mounting substrate 3 side are exposed to the outside with the through-portion 61 interposed therebetween.

The first electronic component 4A is the transmission and reception filter 17, in the same manner as the high-frequency module 1 according to Embodiment 1. The first electronic component 4A has the first signal terminal 44A. The first signal terminal 44A is, for example, a bump. The first signal terminal 44A is an input terminal or an output terminal of the transmission and reception filter 17 as the first electronic component 4A. The main surface 41 of the first electronic component 4A opposite to the mounting substrate 3 side is in contact with the metal electrode layer 6. Therefore, heat generated in the first electronic component 4A can be emitted through the metal electrode layer 6.

In the same manner as the high-frequency module 1 according to Embodiment 1, the second electronic component 4B is the transmission filter 12A. The second electronic component 4B has the second signal terminal 44B. The second signal terminal 44B is, for example, a bump. The second signal terminal 44B is an input terminal or an output terminal of the transmission filter 12A as the second electronic component 4B. The main surface 41 of the second electronic component 4B opposite to the mounting substrate 3 side is in contact with the metal electrode layer 6. Therefore, heat generated in the second electronic component 4B can be emitted through the metal electrode layer 6.

In the high-frequency module 1h according to Embodiment 9, as illustrated in FIG. 11, the through-portion 61 is located between the first signal terminal 44A of the first electronic component 4A and the second signal terminal 44B of the second electronic component 4B, in the plan view in the thickness direction D1 of the mounting substrate 3.

The metal electrode member 7 is a member for providing isolation between the first electronic component 4A and the second electronic component 4B. A material of the metal electrode member 7 is, for example, copper or a copper alloy. An end surface of the metal electrode member 7 opposite to the mounting substrate 3 side is in contact with the metal electrode layer 6 on the second electronic component 4B side with respect to the through-portion 61. That is, the metal electrode member 7 does not overlap with the through-portion 61 in the plan view in the thickness direction D1 of the mounting substrate 3. In addition, an end surface of the metal electrode member 7 on the mounting substrate 3 side is in contact with a through-electrode 35B that penetrates through the mounting substrate 3 in the thickness direction D1 of the mounting substrate 3. The through-electrode 35B is connected to the ground terminal 86. In addition, the metal electrode member 7 is formed over a total length of the mounting substrate 3 in a third direction (the direction orthogonal to the first direction D1 and the second direction D2).

Further, in the high-frequency module 1h according to Embodiment 9, the metal electrode layer 6 is not in contact with the ground layer 34 of the mounting substrate 3, and is in contact with the ground terminal 86 at an outer peripheral portion covering the outer peripheral surface 33 of the mounting substrate 3 and the outer peripheral surface of the resin layer 51.

Therefore, in the high-frequency module 1h according to Embodiment 9, the heat generated in the first electronic component 4A can be emitted to the external substrate 304 through the metal electrode layer 6 and the ground terminal 86. Further, as for the second electronic component 4B, the heat generated in the second electronic component 4B can be emitted to the external substrate 304 through the metal electrode layer 6 and the ground terminal 86, and emitted to the external substrate 304 through the metal electrode layer 6, the metal electrode member 7, the through-electrode 35B, and the ground terminal 86.

### (2) Effect

In the same manner as the high-frequency module 1 according to Embodiment 1, also in the high-frequency module 1h according to Embodiment 9, the through-portion 61 of the metal electrode layer 6 is located between the first signal terminal 44A and the second signal terminal 44B, in the plan view in the thickness direction D1 of the mounting substrate 3. Therefore, it is possible to reduce a decrease in isolation between the first signal terminal 44A and the second signal terminal 44B.

### Embodiment 10

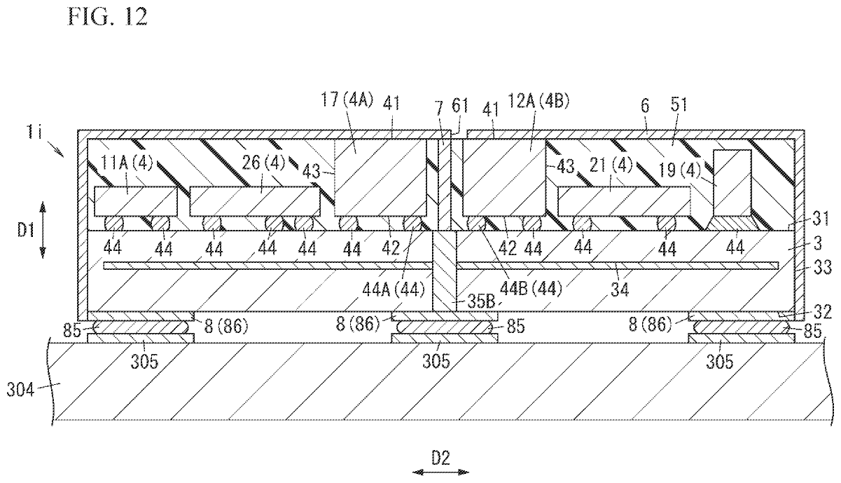

As illustrated in FIG. 12, a high-frequency module 1i according to Embodiment 10 is different from the high-frequency module 1h according to Embodiment 9 (see FIG. 11) in that the metal electrode member 7 is in contact with the metal electrode layer 6 on the first electronic component 4A side with respect to the through-portion 61.

### (1) Configuration

As illustrated in FIG. 12, the high-frequency module 1i according to Embodiment 10 includes the mounting substrate 3, the plurality of electronic components 4, and the plurality of external connection electrodes 8. The high-frequency module 1i further includes the resin layer 51 and the metal electrode layer 6. The high-frequency module 1i further includes the metal electrode member 7. Regarding the high-frequency module 1i according to Embodiment 10, the same components as the high-frequency module 1h according to Embodiment 9 are attached with the same reference numerals, and the description thereof will be omitted.

In the high-frequency module 1i according to Embodiment 10, as illustrated in FIG. 12, the metal electrode member 7 is in contact with the metal electrode layer 6 on the first electronic component 4A side with respect to the through-portion 61 of the metal electrode layer 6. That is, also in the high-frequency module 1i according to Embodiment 10, the metal electrode member 7 does not overlap with the through-portion 61 in the plan view in the thickness direction D1 of the mounting substrate 3.

In the high-frequency module 1i according to Embodiment 10, as for the first electronic component 4A, heat generated in the first electronic component 4A can be emitted to the external substrate 304 through the metal electrode layer 6 and the ground terminal 86, and emitted to the external substrate 304 through the metal electrode layer 6, the metal electrode member 7, the through-electrode 35B, and the ground terminal 86. Further, as for the second electronic component 4B, heat generated in the second electronic component 4B can be emitted to the external substrate 304 through the metal electrode layer 6 and the ground terminal 86.

### (2) Effect

In the same manner as the high-frequency module 1 according to Embodiment 1, also in the high-frequency module 1i according to Embodiment 10, the through-portion 61 of the metal electrode layer 6 is located between the first signal terminal 44A and the second signal terminal 44B, in the plan view in the thickness direction D1 of the mounting substrate 3. Therefore, it is possible to reduce a decrease in isolation between the first signal terminal 44A and the second signal terminal 44B.

### Embodiment 11

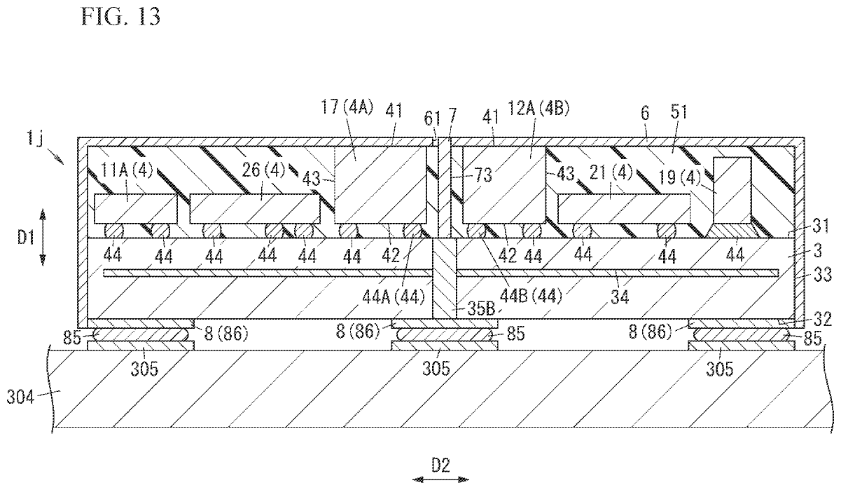

As illustrated in FIG. 13, a high-frequency module 1j according to Embodiment 11 is different from the high-frequency module 1h according to Embodiment 9 (see FIG. 11) in that the metal electrode member 7 is exposed from the metal electrode layer 6.

### (1) Configuration

As illustrated in FIG. 13, the high-frequency module 1j according to Embodiment 11 includes the mounting substrate 3, the plurality of electronic components 4, and the plurality of external connection electrodes 8. The high-frequency module 1j further includes the resin layer 51 and the metal electrode layer 6. The high-frequency module 1j further includes the metal electrode member 7. Regarding the high-frequency module 1i according to Embodiment 11, the same components as the high-frequency module 1h according to Embodiment 9 are attached with the same reference numerals, and the description thereof will be omitted.

In the high-frequency module 1j according to Embodiment 11, as illustrated in FIG. 13, the metal electrode member 7 is exposed from the metal electrode layer 6 in the thickness direction D1 of the mounting substrate 3. More specifically, the metal electrode member 7 is exposed from the metal electrode layer 6 through the through-portion 61 of the metal electrode layer 6. That is, the metal electrode member 7 overlaps with the through-portion 61 in the plan view in the thickness direction D1 of the mounting substrate 3. In addition, an end portion of the outer peripheral surface 73 of the metal electrode member 7 opposite to the mounting substrate 3 side is in contact with the metal electrode layer 6 on the second electronic component 4B side with respect to the through-portion 61.

### (2) Effect

In the same manner as the high-frequency module 1 according to Embodiment 1, also in the high-frequency module 1j according to Embodiment 11, the through-portion 61 of the metal electrode layer 6 is located between the first signal terminal 44A and the second signal terminal 44B, in the plan view in the thickness direction D1 of the mounting substrate 3. Therefore, it is possible to reduce a decrease in isolation between the first signal terminal 44A and the second signal terminal 44B.

### Embodiment 12

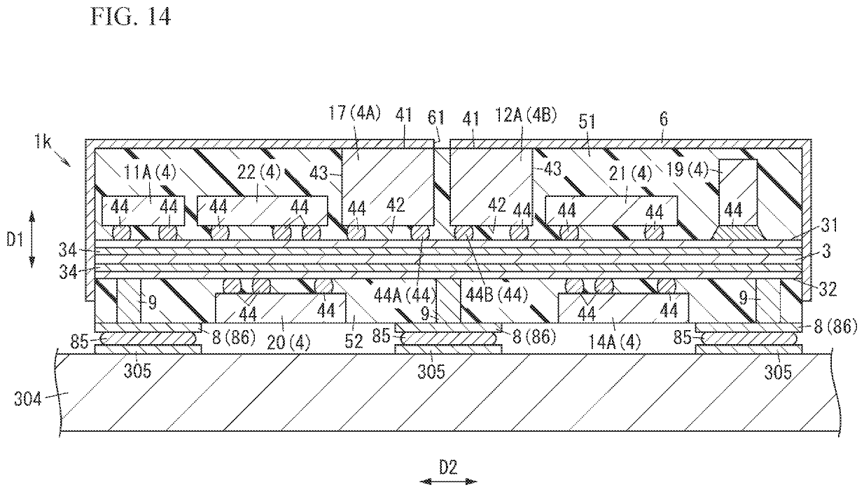

As illustrated in FIG. 14, a high-frequency module 1k according to Embodiment 12 is different from the high-frequency module 1 according to Embodiment 1 in that the electronic component 4 is disposed on each of the first main surface 31 and the second main surface 32 of the mounting substrate 3.

### (1) Configuration

As illustrated in FIG. 14, the high-frequency module 1k according to Embodiment 12 includes the mounting substrate 3, the plurality of electronic components 4, and the plurality of external connection electrodes 8. The high-frequency module 1k further includes the resin layer 51 (hereinafter, referred to as a “first resin layer 51”) and the metal electrode layer 6. The high-frequency module 1k further includes a second resin layer 52 and a plurality of connection terminals 9. Regarding the high-frequency module 1k according to Embodiment 12, the same components as the high-frequency module 1 according to Embodiment 1 are attached with the same reference numerals, and the description thereof will be omitted.

In the high-frequency module 1k according to Embodiment 12, the electronic component 4 is disposed on each of the first main surface 31 and the second main surface 32 of the mounting substrate 3. In the example in FIG. 14, among the plurality of electronic components 4, the electronic components 4 disposed on the first main surface 31 of the mounting substrate 3 are the power amplifier 11A, the transmission filter 12A, the transmission and reception filter 17, the matching circuit 19, the first switch 21, and the second switch 22. In addition, in the example in FIG. 14, among the plurality of electronic components 4, the electronic components 4 disposed on the second main surface 32 of the mounting substrate 3 are the low-noise amplifier 14A and the controller 20.

The first resin layer 51 covers the electronic components 4 disposed on the first main surface 31 of the mounting substrate 3, among the plurality of electronic components 4. Here, the first resin layer 51 covers the outer peripheral surfaces 43 of the electronic components 4 disposed on the first main surface 31 of the mounting substrate 3. The first resin layer 51 covers the main surface 41 on an opposite side of the mounting substrate 3 side of the remaining electronic components 4 other than the first electronic component 4A and the second electronic component 4B, among the electronic components 4 mounted on the first main surface 31 of the mounting substrate 3.

The second resin layer 52 covers the electronic components 4 disposed on the second main surface 32 of the mounting substrate 3 among the plurality of electronic components 4, and the plurality of connection terminals 9. Here, the second resin layer 52 covers the outer peripheral surfaces 43 of the electronic components 4 and outer peripheral surfaces of the plurality of connection terminals 9 disposed on the second main surface 32 of the mounting substrate 3. A material of the second resin layer 52 may be the same as or different from the material of the first resin layer 51.

The plurality of connection terminals 9 are disposed on the second main surface 32 of the mounting substrate 3. The plurality of connection terminals 9 are columnar (for example, cylindrical) electrodes provided on the second main surface 32 of the mounting substrate 3. Materials of the plurality of connection terminals 9 are, for example, metal (for example, copper, copper alloy, and the like). Each of the plurality of connection terminals 9 includes a base end portion joined to the second main surface 32 of the mounting substrate 3 and a tip portion opposite to the base end portion, in the thickness direction D1 of the mounting substrate 3. The tip portion of each of the plurality of connection terminals 9 may include, for example, a gold plating layer. The plurality of connection terminals 9 are terminals for connecting the mounting substrate 3 and the ground terminal 86.

In the high-frequency module 1k according to Embodiment 12, the mounting substrate 3 has a plurality of ground layers 34 as illustrated in FIG. 14. At least a part of an outer peripheral surface of each of the plurality of ground layers 34 is in contact with the metal electrode layer 6. Therefore, a potential of the metal electrode layer 6 can be set to be the same as a potential of the ground layer 34.

In the high-frequency module 1k according to Embodiment 12, the metal electrode layer 6 has the through-portion 61, in the same manner as the high-frequency module 1 according to Embodiment 1. A cross-sectional shape of the through-portion 61 has a rectangular shape. Further, the through-portion 61 is formed over a total length of the mounting substrate 3 in a third direction (a direction orthogonal to the first direction D1 and the second direction D2) which is a direction orthogonal to (intersecting with) the thickness direction D1 of the mounting substrate 3. In the high-frequency module 1k according to Embodiment 12, as illustrated in FIG. 14, the through-portion 61 is located between the first signal terminal 44A of the first electronic component 4A and the second signal terminal 44B of the second electronic component 4B, in the plan view in the thickness direction D1 of the mounting substrate 3.

### (2) Effect

In the same manner as the high-frequency module 1 according to Embodiment 1, also in the high-frequency module 1k according to Embodiment 12, the through-portion 61 of the metal electrode layer 6 is located between the first signal terminal 44A and the second signal terminal 44B, in the plan view in the thickness direction D1 of the mounting substrate 3. Therefore, it is possible to reduce a decrease in isolation between the first signal terminal 44A and the second signal terminal 44B.

### Modification Example

Embodiments 1 to 12 and the like described above are merely one of various embodiments of the present disclosure. Embodiments 1 to 12 and the like described above can have various modifications according to the design, and different components of different embodiments may be combined as appropriate.

Each of the plurality of transmission filters 12A and 12B, the plurality of reception filters 15A and 15B, and the transmission and reception filter 17 according to Embodiments 1 to 12 is not limited to a surface acoustic wave filter, and may be, for example, a bulk acoustic wave (BAW) filter. A resonator in the BAW filter is, for example, a film bulk acoustic resonator (FBAR) or a solidly mounted resonator (SMR). The BAW filter has a substrate. The substrate is, for example, a silicon substrate.

Further, each of the plurality of transmission filters 12A and 12B, the plurality of reception filters 15A and 15B, and the transmission and reception filter 17 according to Embodiments 1 to 12 is not limited to a ladder filter, and may be, for example, a longitudinally coupled resonator-type surface acoustic wave filter.

In addition, the acoustic wave filter described above is an acoustic wave filter that uses a surface acoustic wave or a bulk acoustic wave, and is not limited thereto. For example, an acoustic wave filter that uses a boundary acoustic wave, a plate wave, or the like may be used.

Further, the communication device 300 according to Embodiment 1 may include any one of the high-frequency modules 1a to 1k instead of the high-frequency module 1.

In the present specification, “an element is disposed on a first main surface of a substrate” includes not only a case where the element is directly mounted on the first main surface of the substrate but also a case where the element is disposed in a space on the first main surface side between the space on the first main surface side and a space on the second main surface side separated by the substrate. That is, “the element is disposed on the first main surface of the substrate” includes a case where the element is mounted on the first main surface of the substrate with another circuit element, an electrode, or the like interposed therebetween. The element is, for example, the electronic component 4, and is not limited to the electronic component 4. The substrate is, for example, the mounting substrate 3. In a case where the substrate is the mounting substrate 3, the first main surface is the first main surface 31 and the second main surface is the second main surface 32.

In the present specification, “an element is disposed on a second main surface of a substrate” includes not only a case where the element is directly mounted on the second main surface of the substrate but also a case where the element is disposed in a space on the second main surface side between the space on the first main surface side and a space on the second main surface side separated by the substrate. That is, “the element is disposed on the second main surface of the substrate” includes a case where the element is mounted on the second main surface of the substrate with another circuit element, an electrode, or the like interposed therebetween. The element is, for example, the electronic component 4 or the connection terminal 9, and is not limited to the electronic component 4 or the connection terminal 9. The substrate is, for example, the mounting substrate 3. In a case where the substrate is the mounting substrate 3, the first main surface is the first main surface 31 and the second main surface is the second main surface 32.

In the present specification, “a first element overlaps with a second element in a plan view in a thickness direction of a substrate” includes a case where all of the first element overlaps with all of the second element, a case where all of the first element overlaps with a part of the second element, a case where a part of the first element overlaps with all of the second element, and a case where a part of the first element overlaps with a part of the second element, in the plan view in the thickness direction of the substrate. In short, “the first element overlaps with the second element in the plan view in the thickness direction of the substrate” means that “at least a part of the first element overlaps with at least a part of the second element”. The first element is, for example, the metal electrode member 7. The second element is, for example, the through-portion 61 of the metal electrode layer 6. The substrate is, for example, the mounting substrate 3.

In the present specification, “a third element is disposed between a first element and a second element in a plan view in a thickness direction of a substrate” means that at least one of a plurality of line segments connecting any point in the first element and any point in the second element passes through a region of the third element in the plan view in the thickness direction of the substrate. In addition, the plan view in the thickness direction of the substrate means that the substrate and an electronic component mounted on the substrate are orthographically projected onto a plane parallel to a main surface of the substrate. The substrate is, for example, the mounting substrate 3.

(Aspects)

The following aspects are disclosed in the present specification.

According to a first aspect, there is provided a high-frequency module (1; 1a; 1b; 1e to 1k) includes a mounting substrate (3), a first electronic component (4A), a second electronic component (4B), a resin layer (51), and a metal electrode layer (6). The mounting substrate (3) has a first main surface (31) and a second main surface (32) facing each other. The first electronic component (4A) and the second electronic component (4B) are disposed on the first main surface (31) of the mounting substrate (3). The resin layer (51) is disposed on the first main surface (31) of the mounting substrate (3), and covers at least a part of an outer peripheral surface (43) of the first electronic component (4A) and at least a part of an outer peripheral surface (43) of the second electronic component (4B). The metal electrode layer (6) covers at least a part of the resin layer (51), and overlaps with at least a part of the first electronic component (4A) and at least a part of the second electronic component (4B) in a plan view in a thickness direction (D1) of the mounting substrate (3). At least a part of a main surface (41) of the first electronic component (4A) opposite to the mounting substrate (3) side is in contact with the metal electrode layer (6). The first electronic component (4A) has a first signal terminal (44A). The second electronic component (4B) has a second signal terminal (44B). The metal electrode layer (6) has a through-portion (61) between the first signal terminal (44A) and the second signal terminal (44B) in the plan view in the thickness direction (D1) of the mounting substrate (3).

According to the aspect, it is possible to reduce a decrease in isolation between the first signal terminal (44A) and the second signal terminal (44B). Further, according to the aspect, heat generated in the first electronic component (4A) can be emitted through the metal electrode layer (6).

According to the first aspect, in the high-frequency module (1) according to a second aspect, at least a part of the main surface (41) of the second electronic component (4B) opposite to the mounting substrate (3) side is in contact with the metal electrode layer (6).

According to the aspect, heat generated in the second electronic component (4B) can be emitted through the metal electrode layer (6).

According to a third aspect, there is provided a high-frequency module (1d) including a mounting substrate (3), a first electronic component (4A), a second electronic component (4B), a first metal member (10A), a second metal member (10B), a resin layer (51), and a metal electrode layer (6). The mounting substrate (3) has a first main surface (31) and a second main surface (32) facing each other. The first electronic component (4A) and the second electronic component (4B) are disposed on the first main surface (31) of the mounting substrate (3). The first metal member (10A) is disposed on the main surface (41) of the first electronic component (4A) opposite to the mounting substrate (3) side. The second metal member (10B) is disposed on the main surface (41) of the second electronic component (4B) opposite to the mounting substrate (3) side. The resin layer (51) is disposed on the first main surface (31) of the mounting substrate (3), and covers at least a part of an outer peripheral surface (43) of the first electronic component (4A), at least a part of an outer peripheral surface (43) of the second electronic component (4B), at least a part of an outer peripheral surface (103) of the first metal member (10A), and at least a part of an outer peripheral surface (103) of the second metal member (10B). The metal electrode layer (6) covers at least a part of the resin layer (51), and overlaps with at least a part of the first metal member (10A) and at least a part of the second metal member (10B) in a plan view in a thickness direction (D1) of the mounting substrate (3). At least a part of a main surface (101) of the first metal member (10A) opposite to the mounting substrate (3) side is in contact with the metal electrode layer (6). At least a part of a main surface (101) of the second metal member (10B) opposite to the mounting substrate (3) side is in contact with the metal electrode layer (6). The first electronic component (4A) has a first signal terminal (44A). The second electronic component (4B) has a second signal terminal (44B). The metal electrode layer (6) has a through-portion (61) between the first signal terminal (44A) and the second signal terminal (44B) in the plan view in the thickness direction (D1) of the mounting substrate (3).

According to the aspect, it is possible to reduce a decrease in isolation between the first signal terminal (44A) and the second signal terminal (44B). In addition, heat generated in the first electronic component (4A) and the second electronic component (4B) can be emitted through the first metal member (10A), the second metal member (10B), and the metal electrode layer (6).

According to any one of the first to third aspects, in the high-frequency module (1; 1a to 1k) according to a fourth aspect, each of the first electronic component (4A) and the second electronic component (4B) is a high-frequency component (4A, 4B) provided in a signal path (T1, T2) through which a transmission signal passes.

According to the aspect, it is possible to reduce an influence of the heat generation of the high-frequency component (4A, 4B).

According to the fourth aspect, in the high-frequency module (1; 1a to 1k) according to a fifth aspect, the high-frequency component (4A, 4B) is a transmission filter (12A, 12B), a transmission and reception filter (17), or a power amplifier (11A).

According to any one of the first to third aspects, in the high-frequency module (1e) according to a sixth aspect, the first electronic component (4A) is a first inductor (131) provided on a signal path (T1) through which a transmission signal passes. The second electronic component (4B) is a second inductor (161) provided in a signal path (R1) through which a reception signal passes.

According to the aspect, it is possible to reduce a decrease in isolation between the first inductor (131) and the second inductor (161).

According to any one of the first to sixth aspects, in the high-frequency module (1; 1a to 1k) according to a seventh aspect, a length (L2) of the through-portion (61) in one direction (D3) intersecting with the thickness direction (D1) of the mounting substrate (3) is longer than a length (L11) of the first electronic component (4A) in the one direction (D3).

According to the aspect, it is possible to more effectively reduce the isolation between the first signal terminal (44A) and the second signal terminal (44B).

According to any one of the first to seventh aspects, in the high-frequency module (1; 1a to 1k) according to an eighth aspect, a length (L2) of the through-portion (61) in one direction (D3) interacting with the thickness direction (D1) of the mounting substrate (3) is longer than a length (L12) of the second electronic component (4B) in the one direction (D3).

According to the aspect, it is possible to more effectively reduce the isolation between the first signal terminal (44A) and the second signal terminal (44B).

According to a ninth aspect, there is provided a high-frequency module (1c) including a mounting substrate (3), an electronic component (4A), a resin layer (51), and a metal electrode layer (6). The mounting substrate (3) has a first main surface (31) and a second main surface (32) facing each other. The electronic component (4A) is disposed on the first main surface (31) of the mounting substrate (3). The resin layer (51) is disposed on the first main surface (31) of the mounting substrate (3), and covers at least a part of the outer peripheral surface (43) of the electronic component (4A). The metal electrode layer (6) covers at least a part of the resin layer (51), and overlaps with at least a part of the electronic component (4A) in a plan view in the thickness direction (D1) of the mounting substrate (3). At least a part of a main surface (41) of the electronic component (4A) opposite to the mounting substrate (3) side is in contact with the metal electrode layer (6). The electronic component (4A) has a first signal terminal (44A) and a second signal terminal (44B). The metal electrode layer (6) has a through-portion (61) between the first signal terminal (44A) and the second signal terminal (44B) in the plan view in the thickness direction (D1) of the mounting substrate (3).

According to the aspect, it is possible to reduce a decrease in isolation between the first signal terminal (44A) and the second signal terminal (44B).

According to any one of the first to ninth aspects, in the high-frequency module (1; 1a to 1d; 1g to 1k) according to a tenth aspect, the through-portion (61) is formed over a total length (L3) of the mounting substrate (3) in one direction (D3) intersecting with the thickness direction (D1) of the mounting substrate (3).

According to the aspect, it is possible to more effectively reduce the isolation between the first signal terminal (44A) and the second signal terminal (44B).

According to any one of the first to ninth aspects, in the high-frequency module (1f) according to an eleventh aspect, the through-portion (61) is formed to have an L shape in the plan view in the thickness direction (D1) of the mounting substrate (3).

According to the aspect, it is possible to more effectively reduce the isolation between the first signal terminal (44A) and the second signal terminal (44B).

According to any one of the first to eleventh aspects, the high-frequency module (1j) according to a twelfth aspect further includes a metal electrode member (7). The metal electrode member (7) is disposed on the first main surface (31) of the mounting substrate (3), and is connected to a ground. The metal electrode member (7) overlaps with the through-portion (61) in the plan view in the thickness direction (D1) of the mounting substrate (3).

According to the aspect, it is possible to more effectively reduce the isolation between the first signal terminal (44A) and the second signal terminal (44B).

According to the twelfth aspect, in the high-frequency module (1j) according to a thirteenth aspect, the metal electrode member (7) is exposed from the metal electrode layer (6) in the thickness direction (D1) of the mounting substrate (3)

According to the aspect, it is possible to more effectively reduce the isolation between the first signal terminal (44A) and the second signal terminal (44B).

According to any one of the first to eleventh aspects, the high-frequency module (1h; 1i) according to a fourteenth aspect further includes a metal electrode member (7). The metal electrode member (7) is disposed on the first main surface (31) of the mounting substrate (3), and is connected to a ground. The metal electrode member (7) does not overlap with the through-portion (61) in the plan view in the thickness direction (D1) of the mounting substrate (3).

According to the aspect, it is possible to more effectively reduce the isolation between the first signal terminal (44A) and the second signal terminal (44B).

According to a fifteenth aspect, there is provided a communication device (300) including the high-frequency module (1; 1a to 1k) according to any one of the first to fourteenth aspects, and a signal processing circuit (301). The signal processing circuit (301) is connected to the high-frequency module (1; 1a to 1k).

According to the aspect, it is possible to reduce a decrease in isolation between the first signal terminal (44A) and the second signal terminal (44B).

### REFERENCE SIGNS LIST

1, 1a to 1k HIGH-FREQUENCY MODULE
10A FIRST METAL MEMBER
10B SECOND METAL MEMBER
101 MAIN SURFACE
103 OUTER PERIPHERAL SURFACE
11A, 11B POWER AMPLIFIER
12A, 12B TRANSMISSION FILTER
13A, 13B OUTPUT MATCHING CIRCUIT
131 FIRST INDUCTOR
14A, 14B LOW-NOISE AMPLIFIER
15A, 15B RECEPTION FILTER
16A, 16B INPUT MATCHING CIRCUIT
161 SECOND INDUCTOR
17 TRANSMISSION AND RECEPTION FILTER
18A, 18B, 18C MATCHING CIRCUIT
19 MATCHING CIRCUIT
20 CONTROLLER
21 FIRST SWITCH
22 SECOND SWITCH
23 THIRD SWITCH
24 FOURTH SWITCH
3 MOUNTING SUBSTRATE
31 FIRST MAIN SURFACE
32 SECOND MAIN SURFACE
33 OUTER PERIPHERAL SURFACE
34 GROUND LAYER
35 VIA-CONDUCTOR
4 ELECTRONIC COMPONENT
4A FIRST ELECTRONIC COMPONENT (HIGH-FREQUENCY COMPONENT)
4B SECOND ELECTRONIC COMPONENT (HIGH-FREQUENCY COMPONENT)
41 MAIN SURFACE
42 MAIN SURFACE
43 OUTER PERIPHERAL SURFACE
44 CONNECTION PORTION
44A FIRST SIGNAL TERMINAL
44B SECOND SIGNAL TERMINAL
51 RESIN LAYER
52 SECOND RESIN LAYER
6 METAL ELECTRODE LAYER
61 THROUGH-PORTION
7 METAL ELECTRODE MEMBER
73 OUTER PERIPHERAL SURFACE
8 EXTERNAL CONNECTION ELECTRODE
81 ANTENNA TERMINAL
82A, 82B SIGNAL INPUT TERMINAL
83A, 83B SIGNAL OUTPUT TERMINAL
84 CONTROL TERMINAL
85 CONNECTION PORTION
86 GROUND TERMINAL
9 CONNECTION TERMINAL
300 COMMUNICATION DEVICE
301 SIGNAL PROCESSING CIRCUIT
302 RF SIGNAL PROCESSING CIRCUIT
303 BASEBAND SIGNAL PROCESSING CIRCUIT
304 EXTERNAL SUBSTRATE
305 EXTERNAL CONNECTION ELECTRODE
306 MAIN SURFACE
D1 THICKNESS DIRECTION (FIRST DIRECTION)
D2 SECOND DIRECTION
D3 ONE DIRECTION (THIRD DIRECTION)
L11 LENGTH OF FIRST ELECTRONIC COMPONENT
L12 LENGTH OF SECOND ELECTRONIC COMPONENT
L2 LENGTH OF THROUGH-PORTION
L3 TOTAL LENGTH OF SUBSTRATE
T1, T2 TRANSMISSION PATH
R1, R2 RECEPTION PATH
T11 FIRST TRANSMISSION PATH
T12 SECOND TRANSMISSION PATH
R11 FIRST RECEPTION PATH
R12 SECOND RECEPTION PATH

1. A high-frequency module comprising:
a mounting substrate that has a first main surface and a second main surface facing each other;
a first electronic component and a second electronic component on the first main surface of the mounting substrate;
a resin layer that is on the first main surface of the mounting substrate, and that covers at least a part of an outer peripheral surface of the first electronic component and at least a part of an outer peripheral surface of the second electronic component; and
a metal electrode layer that covers at least a part of the resin layer, and that overlaps at least a part of the first electronic component and at least a part of the second electronic component in a plan view in a thickness direction of the mounting substrate,
wherein at least a part of a main surface of the first electronic component opposite to a mounting substrate side is in contact with the metal electrode layer,
wherein the first electronic component comprises a first signal terminal,
wherein the second electronic component comprises a second signal terminal, and
wherein the metal electrode layer has a through-portion between the first signal terminal and the second signal terminal in the plan view in the thickness direction of the mounting substrate.

2. The high-frequency module according to claim 1, wherein at least a part of a main surface of the second electronic component opposite to the mounting substrate side is in contact with the metal electrode layer.

3. A high-frequency module comprising:
a mounting substrate that has a first main surface and a second main surface facing each other;
a first electronic component and a second electronic component on the first main surface of the mounting substrate;
a first metal member on a main surface of the first electronic component opposite to a mounting substrate side;
a second metal member on a main surface of the second electronic component opposite to the mounting substrate side;
a resin layer that is on the first main surface of the mounting substrate, and that covers at least a part of an outer peripheral surface of the first electronic component, at least a part of an outer peripheral surface of the second electronic component, at least a part of an outer peripheral surface of the first metal member, and at least a part of an outer peripheral surface of the second metal member; and
a metal electrode layer that covers at least a part of the resin layer, and that overlaps at least a part of the first metal member and at least a part of the second metal member in a plan view in a thickness direction of the mounting substrate,
wherein at least a part of a main surface of the first metal member opposite to the mounting substrate side is in contact with the metal electrode layer,
wherein at least a part of a main surface of the second metal member opposite to the mounting substrate side is in contact with the metal electrode layer,
wherein the first electronic component comprises a first signal terminal,
wherein the second electronic component comprises a second signal terminal, and
the metal electrode layer has a through-portion between the first signal terminal and the second signal terminal in the plan view in the thickness direction of the mounting substrate.

4. The high-frequency module according to claim 1, wherein each of the first electronic component and the second electronic component is a high-frequency component in a signal path through which a transmission signal passes.

5. The high-frequency module according to claim 4, wherein the high-frequency component is a transmission filter, a transmission and reception filter, or a power amplifier.

6. The high-frequency module according to claim 1,
wherein the first electronic component is a first inductor in a signal path through which a transmission signal passes, and
wherein the second electronic component is a second inductor in a signal path through which a reception signal passes.

7. The high-frequency module according to claim 1, wherein a length of the through-portion in one direction intersecting with the thickness direction of the mounting substrate is longer than a length of the first electronic component in the one direction.

8. The high-frequency module according to claim 1, wherein a length of the through-portion in one direction intersecting with the thickness direction of the mounting substrate is longer than a length of the second electronic component in the one direction.

9. A high-frequency module comprising:
a mounting substrate that has a first main surface and a second main surface facing each other;
an electronic component on the first main surface of the mounting substrate;
a resin layer that is on the first main surface of the mounting substrate, and that covers at least a part of an outer peripheral surface of the electronic component; and
a metal electrode layer that covers at least a part of the resin layer, and that overlaps at least a part of the electronic component in a plan view in a thickness direction of the mounting substrate,
wherein at least a part of a main surface of the electronic component opposite to a mounting substrate side is in contact with the metal electrode layer,
wherein the electronic component comprises:
a first signal terminal, and
a second signal terminal, and
wherein the metal electrode layer has a through-portion between the first signal terminal and the second signal terminal in the plan view in the thickness direction of the mounting substrate.

10. The high-frequency module according to claim 1, wherein the through-portion is formed over a total length of the mounting substrate in one direction intersecting with the thickness direction of the mounting substrate.

11. The high-frequency module according to claim 1, wherein the through-portion is L-shaped in the plan view in the thickness direction of the mounting substrate.

12. The high-frequency module according to claim 1, further comprising:
a metal electrode on the first main surface of the mounting substrate, and connected to a ground,
wherein the metal electrode overlaps the through-portion in the plan view in the thickness direction of the mounting substrate.

13. The high-frequency module according to claim 12, wherein the metal electrode is exposed from the metal electrode layer in the thickness direction of the mounting substrate.

14. The high-frequency module according to claim 1, further comprising:
a metal electrode on the first main surface of the mounting substrate, and connected to ground,
wherein the metal electrode does not overlap the through-portion in the plan view in the thickness direction of the mounting substrate.

15. A communication device comprising:
the high-frequency module according to claim 1; and
a signal processing circuit connected to the high-frequency module.
